(19) United States
(12) Patent Application Publication
(10) Pub. No.: US 2026/0214988 A1
(43) Pub. Date: Jul. 23, 2026

(54) DISPLAY PANEL HAVING LIGHT-SHIELDING LAYERS

(71) Applicant: Yungu (Gu’an) Technology Co., Ltd., Langfang (CN)

(72) Inventors: Jianjun LU, Langfang (CN); Cuili GAI, Langfang (CN); Enqing GUO, Langfang (CN)

(73) Assignee: Yungu (Gu’an) Technology Co., Ltd., Langfang (CN)

(21) Appl. No.: 19/567,235

(22) Filed: Mar. 15, 2026

(30) Foreign Application Priority Data
Mar. 24, 2025 (CN) 202510352683.5

(51) Int. Cl. H10D 86/40

(52) U.S. Cl. CPC H10D 86/441; H10D 86/421; H10D 86/451

(57) ABSTRACT

The present application discloses a display panel. The display panel includes a substrate; an active layer disposed on one side of the substrate, the active layer including a plurality of channel regions, the channel regions being used to form transistors; and at least two light-shielding layers stacked on a side of the active layer away from the substrate, and an orthographic projection of at least one of the light-shielding layers on the substrate at least partially overlaps an orthographic projection of the channel region on the substrate, and orthographic projections of the at least two light-shielding layers on the substrate cover the orthographic projection of the channel region on the substrate. This can improve the threshold voltage stability of the transistors and ameliorate abnormal display and mura phenomena in the display panel.

### CROSS REFERENCE TO RELATED APPLICATION

The present application claims priority to Chinese Patent Application No. 202510352683.5, filed on Mar. 24, 2025, which is incorporated herein by reference in its entirety.

### FIELD

Embodiments of the present application relate to the field of display technology, and in particular, to a display panel and a display device.

### BACKGROUND

Indium Gallium Zinc Oxide (IGZO) Thin Film Transistors (TFTs) have the advantages of low leakage current and low process cost, which are beneficial for making low refresh rate, medium and large size screens. However, IGZO has poor light stability, and the threshold voltage drift range of TFTs is large, which easily leads to abnormal display or screen mura phenomena.

### SUMMARY

An embodiment of the present application provides a display panel, including: a substrate; an active layer disposed on one side of the substrate, the active layer including a plurality of channel regions, the channel regions being configured to form transistors; and at least two light-shielding layers stacked on a side of the active layer away from the substrate, and an orthographic projection of at least one of the light-shielding layers on the substrate at least partially overlaps an orthographic projection of the channel regions on the substrate, and orthographic projections of the at least two light-shielding layers on the substrate cover the orthographic projection of the channel regions on the substrate.

An embodiment of the present application further provides a display panel, including a plurality of sub-regions and driving signal lines, and an arrangement direction of the sub-regions is the same as an extension direction of the driving signal lines; the display panel further includes: a substrate; a second conductive layer disposed on one side of the substrate, the driving signal lines being located in the second conductive layer; and at least one light-shielding layer disposed on a side of the second conductive layer away from the substrate, and overlapping areas between an orthographic projection of a same driving signal line on the substrate and orthographic projections of the light-shielding layers of different sub-regions on the substrate are the same.

### BRIEF DESCRIPTION OF THE DRAWINGS

FIG. 1 is a schematic cross-sectional structural diagram of a display panel provided by an embodiment of the present application;

FIG. 2 is a schematic circuit diagram of a scan circuit provided by an embodiment of the present application;

FIG. 3 is a schematic top-view structural diagram of a first light-shielding layer provided by an embodiment of the present application;

FIG. 4 is a schematic top-view structural diagram of a second light-shielding layer provided by an embodiment of the present application;

FIG. 5 is a schematic top-view structural diagram illustrating a positional relationship between partial film layers of a gate driving circuit and a first light-shielding layer provided by an embodiment of the present application;

FIG. 6 is a schematic top-view structural diagram illustrating a positional relationship between partial film layers of a gate driving circuit and a first light-shielding layer and a second light-shielding layer provided by an embodiment of the present application;

FIG. 7 is another schematic top-view structural diagram of a first light-shielding layer provided by an embodiment of the present application;

FIG. 8 is another schematic top-view structural diagram of a second light-shielding layer provided by an embodiment of the present application;

FIG. 9 is a schematic structural diagram of a first metal layer of a gate driving circuit provided by an embodiment of the present application;

FIG. 10 is a schematic structural diagram of a second metal layer of a gate driving circuit provided by an embodiment of the present application;

FIG. 11 is a schematic structural diagram of a first metal layer and a second metal layer of a gate driving circuit provided by an embodiment of the present application;

FIG. 12 is a schematic structural diagram of an active layer of a gate driving circuit provided by an embodiment of the present application;

FIG. 13 is a schematic structural diagram of an active layer and a gate layer of a gate driving circuit provided by an embodiment of the present application;

FIG. 14 is a schematic structural diagram of a first metal layer, a second metal layer, and a source-drain layer of a gate driving circuit provided by an embodiment of the present application;

FIG. 15 is a schematic structural diagram of an active layer, a gate layer, and a source-drain layer of a gate driving circuit provided by an embodiment of the present application;

FIG. 16 is a schematic structural diagram of an active layer and a metal layer of a gate driving circuit provided by an embodiment of the present application;

FIG. 17 is a schematic structural diagram of an active layer and a conductive layer of a gate driving circuit provided by an embodiment of the present application;

FIG. 18 is a partially enlarged schematic diagram of a first dashed box P1 in FIG. 5;

FIG. 19 is a partially enlarged schematic diagram of a first dashed box A1 in FIG. 6;

FIG. 20 is a partially enlarged schematic diagram of a second dashed box P2 in FIG. 5;

FIG. 21 is a partially enlarged schematic diagram of a second dashed box A2 in FIG. 6;

FIG. 22 is another schematic cross-sectional structural diagram of a display panel provided by an embodiment of the present application;

FIG. 23 is another schematic cross-sectional structural diagram of a display panel provided by an embodiment of the present application;

FIG. 24 is a schematic top-view structural diagram of driving signal lines and a light-shielding layer provided by an embodiment of the present application;

FIG. 25 is another schematic cross-sectional structural diagram of a display panel provided by an embodiment of the present application;

FIG. 26 is a schematic top-view structural diagram of driving signal lines and a first light-shielding layer and a second light-shielding layer provided by an embodiment of the present application; and

FIG. 27 is a schematic structural diagram of a display device provided by an embodiment of the present application.

### DETAILED DESCRIPTION OF EMBODIMENTS

The following describes the present application in further detail with reference to the accompanying drawings and embodiments. It is to be understood that the specific embodiments described herein are merely for explaining the present application and are not intended to limit the present application. It should also be noted that, for ease of description, only structures related to the present application, rather than the entire structure, are shown in the accompanying drawings.

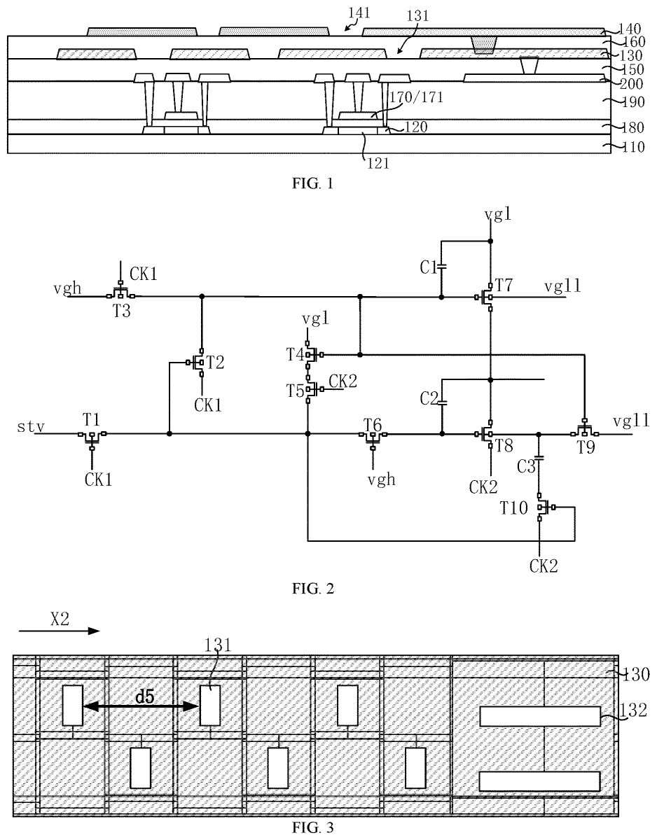

FIG. 1 is a schematic cross-sectional structural diagram of a display panel provided by an embodiment of the present application. As shown in FIG. 1, the display panel includes: a substrate 110; an active layer 120 disposed on one side of the substrate 110, the active layer 120 including a plurality of channel regions 121, the channel regions 121 being configured to form transistors; and at least two light-shielding layers stacked on a side of the active layer 120 away from the substrate 110, and an orthographic projection of at least one of the light-shielding layers on the substrate 110 at least partially overlaps an orthographic projection of the channel regions 121 on the substrate 110, and orthographic projections of the at least two light-shielding layers on the substrate 110 cover the orthographic projection of the channel regions 121 on the substrate 110.

The substrate 110 may be a flexible substrate or a rigid substrate, configured to carry other film layers. The material of the active layer 120 may be a semiconductor material, such as IGZO. By patterning the active layer 120, a plurality of channel regions 121 are formed for forming a plurality of transistors. The display panel includes a display area and a non-display area. When the transistors are located in the display area, the plurality of transistors may form pixel circuits for driving light-emitting devices to emit light. When the transistors are located in the non-display area, the plurality of transistors may form a gate driving circuit for providing driving signals to the pixel circuits in the display area.

The light-shielding layer has a light-shielding function. The larger the area of the light-shielding layer, the smaller the influence of light on the side of the light-shielding layer away from the substrate 110 on the transistor. At least two light-shielding layers are stacked along the thickness direction Z of the substrate 110, and the orthographic projections of the at least two light-shielding layers on the substrate 110 can all be used to cover the active layer 120. The orthographic projection of at least one light-shielding layer on the substrate 110 at least covers part of the orthographic projection of the channel region 121 on the substrate 110, and the orthographic projection of each light-shielding layer on the substrate 110 can partially cover the channel region 121, which is used to block light and prevent light from irradiating the channel region 121. At the same time, through-holes can be provided in the area of the light-shielding layer located in the transistor to ensure the breathability of the film layer on the side of the light-shielding layer close to the substrate 110 through the light-shielding layer, thereby avoiding displacement of the light-shielding layer when gas is generated in the film layer on the side of the light-shielding layer close to the substrate 110, ensuring the reliability of the display panel.

Moreover, the orthographic projections of at least two light-shielding layers on the substrate 110 completely cover the orthographic projection of the channel region 121 on the substrate 110, that is, the orthographic projections of at least two light-shielding layers on the substrate 110 can cross-cover the orthographic projection of the channel region 121 on the substrate 110, thereby completely shielding the channel region 121 through at least two light-shielding layers, preventing the material of the channel region 121 from being irradiated by light on the side of the light-shielding layer away from the substrate 110, ensuring the stability of the channel region 121, thereby improving the threshold voltage stability of the transistor and reducing display abnormalities and mura.

In an embodiment, the orthographic projections of at least two light-shielding layers on the substrate 110 completely cover the orthographic projection of the active layer 120 on the substrate 110, and the at least two light-shielding layers can not only block direct light but also block reflected and/or refracted light, which can improve the light-blocking effect of the at least two light-shielding layers, thereby further improving the stability of the channel region 121 and ameliorating abnormal display and mura phenomena of the display panel.

In this embodiment, by providing at least two light-shielding layers, the orthographic projection of at least one light-shielding layer on the substrate at least covers part of the orthographic projection of the channel region on the substrate, and the orthographic projections of at least two light-shielding layers on the substrate completely cover the orthographic projection of the channel region on the substrate, it can not only block light and prevent light from irradiating the channel region, ensuring the stability of the channel region, thereby improving the threshold voltage stability of the transistor and ameliorating abnormal display and mura phenomena of the display panel. At the same time, it can ensure the breathability of the film layer on the side of the light-shielding layer close to the substrate through the light-shielding layer, thereby avoiding displacement of the light-shielding layer when gas is generated in the film layer on the side of the light-shielding layer close to the substrate, ensuring the reliability of the display panel.

Further referring to FIG. 1, the light-shielding layer includes a first light-shielding layer 130 and a second light-shielding layer 140; the first light-shielding layer 130 and the second light-shielding layer 140 are stacked, the second light-shielding layer 140 is disposed on the side of the first light-shielding layer 130 away from the substrate 110, and the orthographic projection of the channel region 121 on the substrate 110 is located within the orthographic projection of the first light-shielding layer 130 on the substrate 110, and/or, the orthographic projection of the channel region 121 on the substrate 110 is located within the orthographic projection of the second light-shielding layer 140 on the substrate 110.

As shown in FIG. 1, the display panel includes two light-shielding layers, namely a first light-shielding layer 130 and a second light-shielding layer 140. The first light-shielding layer 130 is located on the side of the active layer 120 away from the substrate 110, and the second light-shielding layer 140 is located on the side of the first light-shielding layer 130 away from the substrate 110. For the same channel region 121, the first light-shielding layer 130 can be set to cover part of it, and the second light-shielding layer 140 can be set to cover part of it. At the same time, the first light-shielding layer 130 and the second light-shielding layer 140 completely cover the channel region 121, and the part covered by the first light-shielding layer 130 and the part covered by the second light-shielding layer 140 overlap, thereby cross-covering the same channel region 121 through the first light-shielding layer 130 and the second light-shielding layer 140, achieving complete shielding of the channel region 121 and preventing the material of the channel region 121 from being irradiated by light on the side of the light-shielding layer away from the substrate 110.

In an embodiment, for the same channel region 121, the first light-shielding layer 130 can also be set to completely cover the channel region 121, and/or the second light-shielding layer 130 can be set to completely cover the channel region 121, which can also achieve complete shielding of the channel region 121 and prevent the material of the channel region 121 from being irradiated by light on the side of the light-shielding layer away from the substrate 110. When the first light-shielding layer 130 and the second light-shielding layer 140 have through-holes in the area where the transistor is located, the orthographic projection of the through-holes on the substrate 110 is located on the side of the orthographic projection of the channel region 121 on the substrate 110, which can not only ensure the coverage of the channel region 121 but also ensure the breathability of the film layer on the side of the light-shielding layer close to the substrate 110 through the light-shielding layer, thereby avoiding displacement of the light-shielding layer when gas is generated in the film layer on the side of the light-shielding layer close to the substrate 110, ensuring the reliability of the display panel.

In some embodiments, the display panel further includes a first conductive layer and an electrode layer. The first conductive layer is disposed on the side of the active layer 120 away from the substrate 110, the electrode layer is disposed on the side of the first conductive layer away from the substrate 110, the first light-shielding layer 130 is formed in the first conductive layer, and the second light-shielding layer 140 is formed in the electrode layer.

The display panel includes multiple conductive layers for forming driving circuits and signal lines. In an embodiment, on the side of the active layer 120 away from the substrate 110, a source-drain layer and a signal line layer may be included. The source-drain layer is used to form the source and drain of a transistor, and in an embodiment, the material of the source-drain layer is metal. The signal line layer is disposed on the side of the source-drain layer away from the active layer 120 and is used to form signal lines, in an embodiment, the material of the signal line layer is metal. The signal line layer has relatively large free space. The first conductive layer is disposed on the side of the active layer 120 away from the substrate 110. In this case, the first conductive layer may be the signal line layer, and the first light-shielding layer 130 is formed in the signal line layer. Without affecting the signal lines on the signal line layer, the first light-shielding layer 130 can avoid the need for an additional conductive layer. The electrode layer is disposed on the side of the first conductive layer away from the substrate 110. The display panel includes a display area and a non-display area. The display area is provided with light-emitting devices, and the electrodes of the light-emitting devices are located in the electrode layer. In an embodiment, when the anode of the light-emitting device is connected to the pixel circuit, the electrode layer is used to form the anode of the light-emitting device.

When the cathode of the light-emitting device is connected to the pixel circuit, the electrode layer is used to form the cathode of the light-emitting device. The electrode layer also has relatively large free space. In this case, the second light-shielding layer 140 is formed in the electrode layer, which similarly avoids the need for an additional conductive layer without affecting the electrodes. In an embodiment, the electrode and the second light-shielding layer 140 are insulated by an insulating layer to prevent short circuits between the second light-shielding layer 140 and the electrode, which could affect the display of the light-emitting device.

In some embodiments, the display panel includes a display area and a non-display area at least partially surrounding the display area. Transistors are disposed in the non-display area to form a gate driving circuit.

The transistors in the non-display area may include multiple transistors for forming a multi-stage cascaded gate driving circuit. Each stage of the gate driving circuit may be connected to at least one row of pixel circuits in the display area to provide gate driving signals to the pixel circuits. In an embodiment, the gate driving circuit may include a scanning circuit and/or a light emission control circuit. The scanning circuit provides scanning signals to the transistors in the pixel circuits, and the light emission control circuit provides light emission control signals to the transistors in the pixel circuits.

When the transistors are located in the non-display area, the first light-shielding layer 130 and the second light-shielding layer 140 are at least disposed in the non-display area to completely shield the channel region 121 of the transistors in the gate driving circuit, preventing the material of the channel region 121 of the transistors in the gate driving circuit from being irradiated by light on the side of the light-shielding layers away from the substrate 110. This improves the stability of the channel region 121 of the transistors in the gate driving circuit, enhances the stability of the threshold voltage of the transistors in the gate driving circuit, and thereby improves the consistency of the gate driving signals output by different stages of the gate driving circuit. This results in higher consistency in light emission driven by pixel circuits in different rows, improving the horizontal stripe mura phenomenon of the display panel.

In an embodiment, FIG. 2 is a circuit schematic diagram of a scanning circuit provided by an embodiment of the present application. As shown in FIG. 2, the scanning circuit includes 10 transistors, and the channel region 121 of each transistor is shielded by the first light-shielding layer 130 and the second light-shielding layer 140, thereby improving the threshold voltage stability of each transistor. This enhances the consistency of the gate driving signals output by different stages of the gate driving circuit, resulting in higher consistency in light emission driven by pixel circuits in different rows and improving the horizontal stripe mura phenomenon of the display panel.

As shown in FIG. 1, the display panel further includes a first insulating layer 150 and a second insulating layer 160. The first insulating layer 150 is disposed between the active layer 120 and the first light-shielding layer 130, and the second insulating layer 160 is disposed between the first light-shielding layer 130 and the second light-shielding layer 140.

The first insulating layer 150 is disposed between the active layer 120 and the first light-shielding layer 130 to insulate the active layer 120 and the first light-shielding layer 130. The second insulating layer 160 is disposed between the first light-shielding layer 130 and the second light-shielding layer 140 to insulate the first light-shielding layer 130 and the second light-shielding layer 140.

In some embodiments, the material of the first insulating layer 150 and/or the second insulating layer 160 is an organic material. When the first light-shielding layer 130 covers the first insulating layer 150, it may partially cover the first insulating layer 150. When gas escapes from the first insulating layer 150, it can escape through the uncovered portion of the first insulating layer 150, preventing the first light-shielding layer 130 from shifting when gas escapes from the first insulating layer 150, thereby ensuring the light-shielding reliability of the first light-shielding layer 130. When the first light-shielding layer 130 is the first conductive layer, it also prevents the shifting of other structures on the first conductive layer, improving the reliability of the display panel. Similarly, when the second light-shielding layer 140 covers the second insulating layer 160, it may partially cover the second insulating layer 160. When gas escapes from the second insulating layer 160, it can escape through the uncovered portion of the second insulating layer 160, preventing the second light-shielding layer 140 from shifting when gas escapes from the second insulating layer 160, thereby ensuring the light-shielding reliability of the second light-shielding layer 140. When the second light-shielding layer 140 is the electrode layer, it also prevents the shifting of electrodes in the display area, ensuring the reliability of the display panel.

In an embodiment, when the first conductive layer is a metal layer on the side of the source-drain layer away from the substrate 110, the material of the first insulating layer 150 is an organic material, such as a first planarization layer. When the electrodes of the light-emitting devices are located in the electrode layer, the material of the second insulating layer 160 is an organic material, such as a second planarization layer.

In some embodiments, continuing to refer to FIG. 1, the display panel further includes a gate layer 170. The gate layer 170 is disposed between the active layer 120 and the first light-shielding layer 130. The gate layer 170 includes a gate 171, and the orthographic projection of the gate 171 on the substrate 110 at least partially overlaps with the orthographic projection of the channel region 121 on the substrate 110 to form a transistor.

Continuing to refer to FIG. 1, the display panel further includes a gate insulating layer 180, disposed between the gate layer 170 and the active layer 120. The gate insulating layer 180 is used to insulate the active layer 120 and the gate layer 170. In an embodiment, the material of the gate insulating layer 180 may be an inorganic material.

Still referring to FIG. 1, the display panel may further include an interlayer insulating layer 190 disposed between the gate layer 170 and the source-drain layer 200 for insulating the gate layer 170 from the source-drain layer 200. In an embodiment, the material of the interlayer insulating layer 190 may be an inorganic material.

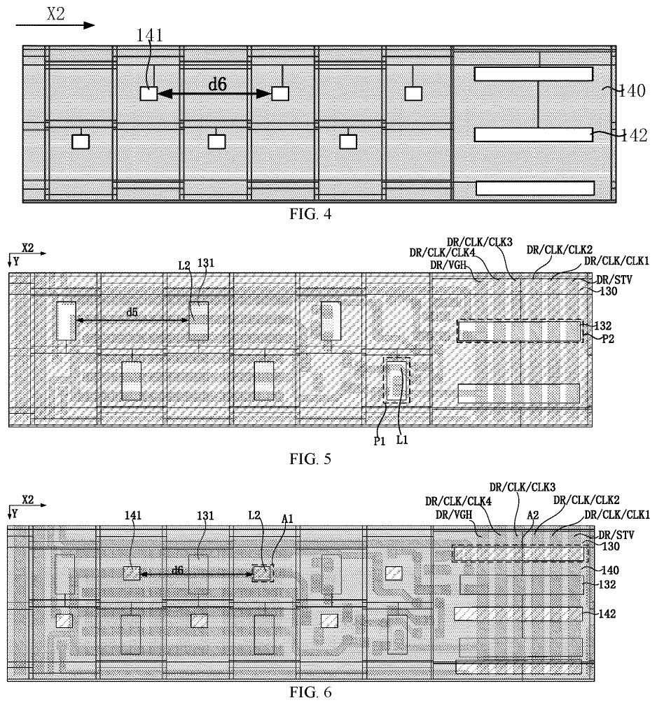

FIG. 3 is a schematic top view of a first light-shielding layer according to an embodiment of the present application, and FIG. 4 is a schematic top view of a second light-shielding layer according to an embodiment of the present application. As shown in FIG. 3 and FIG. 4, a first via hole 131 is provided on the first light-shielding layer 130, and a second via hole 141 is provided on the second light-shielding layer 140; an orthographic projection of the first via hole 131 on the substrate 110 does not overlap with an orthographic projection of the second via hole 141 on the substrate 110.

The first light-shielding layer 130 and the second light-shielding layer 140 may extend in a region where a transistor is located. In an embodiment, when the transistor is used to form a gate driving circuit, and the gate driving circuit is located in a non-display area, the first light-shielding layer 130 and the second light-shielding layer 140 extend in all non-display areas. The first light-shielding layer 130 has a first via hole 131 for partially exposing the first insulating layer 150. When gas overflows from the first insulating layer 150, the gas can overflow through the first via hole 131, preventing the first light-shielding layer 130 from shifting under the action of the gas. The second light-shielding layer 140 has a second via hole 141 for partially exposing the second insulating layer 160. When gas overflows from the second insulating layer 160, the gas can overflow through the second via hole 141, preventing the second light-shielding layer 140 from shifting under the action of the gas.

Since the orthographic projection of the first via hole 131 on the substrate 110 does not overlap with the orthographic projection of the second via hole 141 on the substrate 110, the orthographic projection of the second light-shielding layer 140 on the substrate 110 covers the orthographic projection of the first via hole 131 on the substrate 110, and the orthographic projection of the first light-shielding layer 130 on the substrate 110 covers the orthographic projection of the second via hole 141 on the substrate 110. This allows the orthographic projection of the first light-shielding layer 130 on the substrate 110 and the orthographic projection of the second light-shielding layer 140 on the substrate 110 to completely cover the region where the transistor is located, thereby completely shielding a channel region 121 of the transistor in the non-display area, preventing the material of the channel region 121 from being irradiated by light on a side of the light-shielding layer away from the substrate 110, improving consistency of gate driving signals provided by different stages of gate driving circuits, and ameliorating a horizontal mura phenomenon of the display panel.

In an embodiment, when the transistor is used to form a gate driving circuit, the orthographic projection of the first light-shielding layer 130 on the substrate 110 and the orthographic projection of the second light-shielding layer 140 on the substrate 110 may completely cover the non-display area. In an embodiment, FIG. 5 is a schematic top view illustrating a positional relationship between partial film layers of a gate driving circuit and a first light-shielding layer according to an embodiment of the present application, and FIG. 6 is a schematic top view illustrating a positional relationship between partial film layers of a gate driving circuit and the first light-shielding layer and a second light-shielding layer according to an embodiment of the present application.

As shown in FIG. 5 and FIG. 6, in a region where a gate driving circuit is located, the first light-shielding layer 130 includes a plurality of first via holes 131, and the second light-shielding layer 140 includes a plurality of second via holes 141. The orthographic projection of each first via hole 131 on the substrate 110 does not overlap with the orthographic projection of each second via hole 141 on the substrate 110, and the orthographic projection of the first light-shielding layer 130 on the substrate 110 and the orthographic projection of the second light-shielding layer 140 on the substrate 110 completely cover the orthographic projection of the gate driving circuit on the substrate 110.

In some embodiments, the non-display area includes a plurality of cascaded stages of gate driving circuits, and arrangements of the first via hole and/or the second via hole are identical in different stages of gate driving circuits.

The film layer where the gate driving circuit is located and the light-shielding layer are located in different film layers, and an insulating layer is disposed therebetween. When the orthographic projection of the light-shielding layer on the substrate overlaps with the orthographic projection of the film layer where the gate driving circuit is located on the substrate, a parasitic capacitance is formed between the light-shielding layer and the film layer where the gate driving circuit is located. When the arrangements of the first via holes are identical in different stages of gate driving circuits, it is possible to reduce the difference between different parasitic capacitances when the first light-shielding layer overlaps with different stages of gate driving circuits to form different parasitic capacitances. Similarly, when the arrangements of the second via holes are identical in different stages of gate driving circuits, it is possible to reduce the difference between different parasitic capacitances when the second light-shielding layer overlaps with different stages of gate driving circuits to form different parasitic capacitances. Thereby, consistency of load and delay time of gate driving signals output by different stages of gate driving circuits can be improved, the horizontal mura phenomenon of the display panel is ameliorated, and the display effect of the display panel is enhanced.

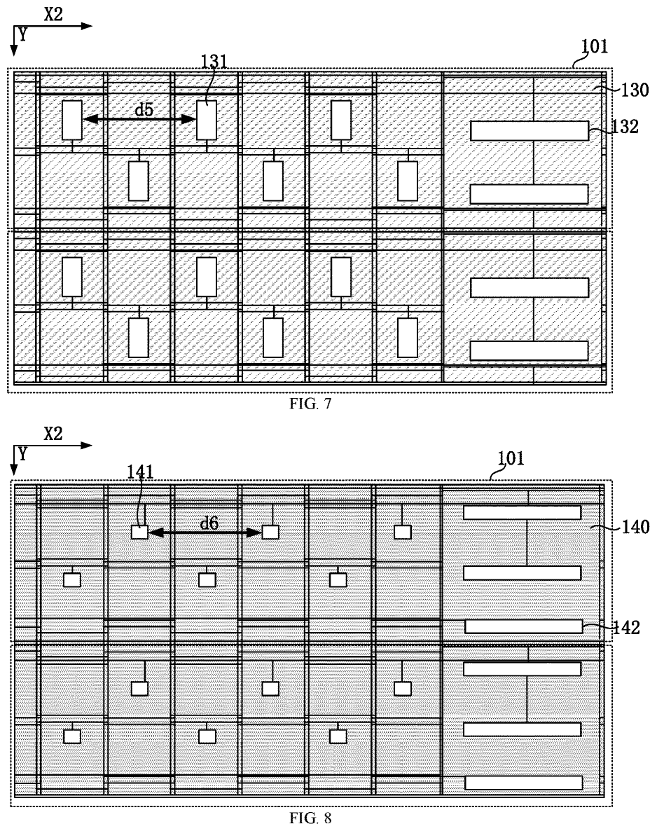

FIG. 7 is a schematic top view of another first light-shielding layer according to an embodiment of the present application, and FIG. 8 is a schematic top view of another second light-shielding layer according to an embodiment of the present application. As shown in FIG. 7 to FIG. 8, the non-display area includes a plurality of sub-regions 101 arranged along a first direction Y; different stages of gate driving circuits are respectively disposed in different sub-regions 101; arrangements of the first via holes 131 are identical in different sub-regions 101, and/or arrangements of the second via holes 141 are identical in different sub-regions 101; and the first direction Y is a cascading direction of the gate driving circuits.

FIG. 7 and FIG. 8 in an embodiment illustrate that the non-display area includes two sub-regions 101 arranged along the first direction Y. Each sub-region 101 may be provided with a stage of gate driving circuit, and the arrangement of different stages of gate driving circuits within each sub-region 101 is the same. When the arrangement of the first via holes 131 is the same in different sub-regions 101, the overlapping positions, overlapping numbers, and overlapping areas of the orthographic projections of the first via holes 131 on the substrate 110 with the orthographic projections of different stages of gate driving circuits on the substrate 110 can be made identical. This can reduce the difference between different parasitic capacitances when the first light-shielding layer 130 and different stages of gate driving circuits form different parasitic capacitances. Similarly, when the arrangement of the second via holes 141 is the same in different sub-regions 101, the overlapping positions, overlapping numbers, and overlapping areas of the orthographic projections of the second via holes 141 on the substrate 110 with the orthographic projections of different stages of gate driving circuits on the substrate 110 can be made identical. This can reduce the difference between different parasitic capacitances when the second light-shielding layer 140 and different stages of gate driving circuits form different parasitic capacitances. Consequently, the load consistency and delay time consistency of gate driving signals output by different stages of gate driving circuits can be improved, the horizontal mura phenomenon of the display panel is ameliorated, and the display effect of the display panel is enhanced.

In an embodiment, FIG. 7 and FIG. 8 in an embodiment illustrate that each sub-region 101 includes one gate driving circuit. When the gate driving circuit includes both a scan circuit and an emission control circuit, each sub-region 101 may simultaneously include a scan circuit and an emission control circuit, which is not limited herein. Continuing to refer to FIG. 2, the gate driving circuit further includes wiring and capacitors. The connection lines are used to connect transistors and/or capacitors. The overlapping area of the orthographic projection of the same connection line on the substrate 110 with the orthographic projections of the first via holes 131 of different sub-regions 101 on the substrate 110 is the same; and/or, the overlapping area of the orthographic projection of the same connection line on the substrate 110 with the orthographic projections of the second via holes 141 of different sub-regions 101 on the substrate 110 is the same. The gate driving circuit includes connection lines. In this case, the connection lines and the light-shielding layer are located in different film layers, with an insulating layer disposed between them.

When the orthographic projection of a connection line on the substrate 110 overlaps with the orthographic projection of the light-shielding layer on the substrate 110, a parasitic capacitance is formed between the connection line and the light-shielding layer. In an embodiment, the connection lines may be located in the source-drain layer, and the light-shielding layer is located on a side of the connection lines away from the substrate 110. When the overlapping area of the orthographic projection of the same connection line on the substrate 110 with the orthographic projections of the first via holes 131 of different sub-regions 101 on the substrate 110 is the same, the difference between different parasitic capacitances can be reduced when the connection lines in different stages of gate driving circuits overlap with the first light-shielding layer 130 to form different parasitic capacitances, thereby reducing the load differences of the connection lines in different stages of gate driving circuits.

Similarly, when the overlapping area of the orthographic projection of the same connection line on the substrate 110 with the orthographic projections of the second via holes 141 of different sub-regions 101 on the substrate 110 is the same, the difference between different parasitic capacitances can be reduced when the connection lines in different stages of gate driving circuits overlap with the second light-shielding layer 140 to form different parasitic capacitances. This also reduces the load differences of the connection lines in different stages of gate driving circuits, improves the load consistency of gate driving signals output by different stages of gate driving circuits, ameliorates the horizontal mura phenomenon of the display panel, and enhances the display effect of the display panel.

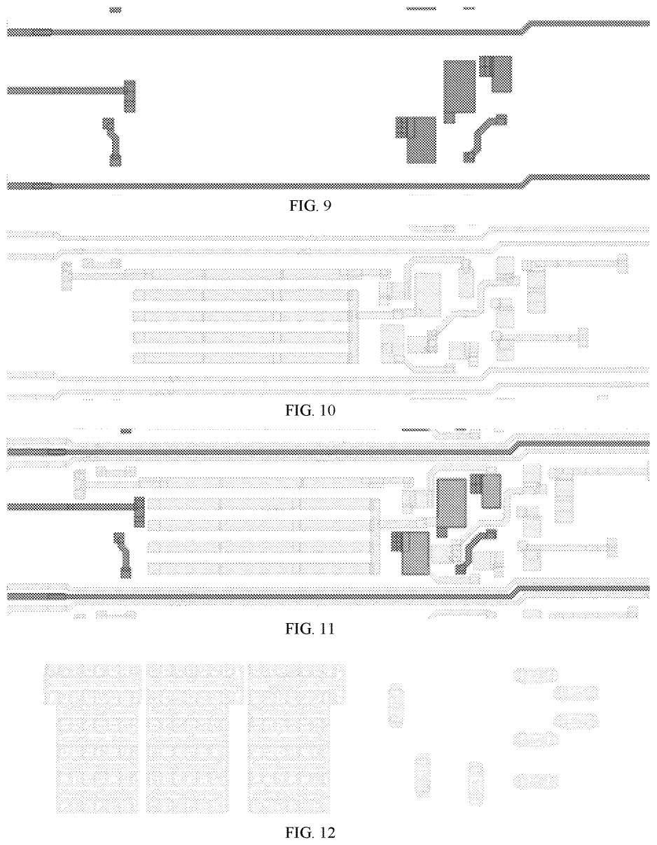

FIG. 9 is a schematic structural diagram of a first metal layer of a gate driving circuit provided by an embodiment of the present application. FIG. 10 is a schematic structural diagram of a second metal layer of a gate driving circuit provided by an embodiment of the present application. FIG. 11 is a schematic structural diagram of a first metal layer and a second metal layer of a gate driving circuit provided by an embodiment of the present application. FIG. 12 is a schematic structural diagram of an active layer of a gate driving circuit provided by an embodiment of the present application.

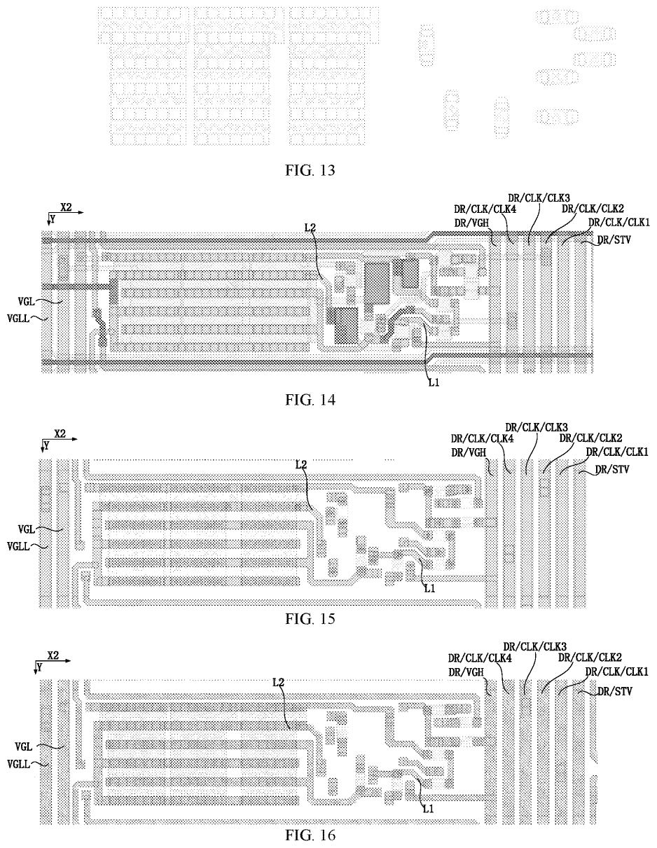

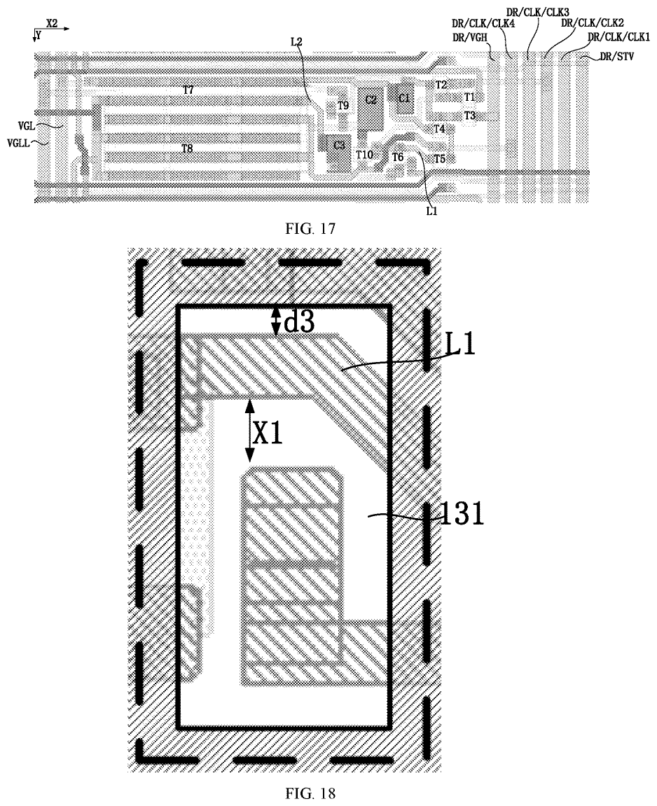

FIG. 13 is a schematic structural diagram of an active layer and a gate layer of a gate driving circuit provided by an embodiment of the present application. FIG. 14 is a schematic structural diagram of a first metal layer, a second metal layer, and a source-drain layer of a gate driving circuit provided by an embodiment of the present application. FIG. 15 is a schematic structural diagram of an active layer, a gate layer, and a source-drain layer of a gate driving circuit provided by an embodiment of the present application. FIG. 16 is a schematic structural diagram of an active layer and a metal layer of a gate driving circuit provided by an embodiment of the present application. FIG. 17 is a schematic structural diagram of an active layer and a conductive layer of a gate driving circuit provided by an embodiment of the present application. As shown in FIG. 1, FIG. 2, FIG. 5, FIG. 6, and FIG. 9 to FIG. 17, the orthographic projection of a connection line on the substrate 110 passes through the orthographic projection of the first via hole 131 on the substrate 110 along the extending direction of the connection line, or the orthographic projection of the connection line on the substrate 110 does not overlap with the orthographic projection of the first via hole 131 on the substrate 110.

FIG. 1, FIG. 2, FIG. 5, FIG. 6, and FIG. 9 to FIG. 17 in an embodiment show that the gate driving circuit includes ten transistors and three capacitors. The ten transistors are respectively a first transistor T1 to a tenth transistor T10, and the three capacitors are respectively a first capacitor C1, a second capacitor C2, and a third capacitor C3. One electrode plate of each of the three capacitors is disposed in a first metal layer M1, and the other electrode plate of each of the three capacitors is disposed in a second metal layer M2. Meanwhile, the second metal layer M2 can serve as a bottom gate of the transistors. A channel region 121 of a transistor is located in an active layer 120, a gate of the transistor is located in a gate layer 170, and connection lines are located in a source-drain layer 200 for connecting different transistors, different capacitors, and transistors and capacitors, and the ten transistors and the three capacitors form the gate driving circuit shown in FIG. 2.

When an orthographic projection of a connection line on the substrate 110 along an extending direction of the connection line passes through an orthographic projection of a first via hole 131 on the substrate 110, if there is a process error during the fabrication of the connection line and the first via hole 131, it can make the overlapping area between the orthographic projection of the connection line in different stages of gate driving circuits on the substrate 110 and the orthographic projection of a first light-shielding layer 130 on the substrate 110 equal, thereby reducing the difference between different parasitic capacitances when the connection lines in different gate driving circuits overlap with the first light-shielding layer 130 to form different parasitic capacitances, and thus reducing the load difference of the connection lines in different stages of gate driving circuits.

In an embodiment, referring to FIG. 5, FIG. 6, and FIG. 14 to FIG. 17, a first electrode of a fifth transistor T5 is connected to a first electrode of a sixth transistor T6 through a first connection line L1. Along the extending direction of the first connection line L1, an orthographic projection of the first connection line L1 on the substrate 110 passes through an orthographic projection of the first via hole 131 on the substrate 110. If there is a process error during the fabrication of the first connection line L1 and the first via hole 131, it can make the overlapping area between the first connection line L1 and the first light-shielding layer 130 in different gate driving circuits equal, thereby reducing the difference between different parasitic capacitances and reducing the load difference of the connection lines in different stages of gate driving circuits.

When an orthographic projection of a connection line on the substrate 110 does not overlap with an orthographic projection of the first via hole 131 on the substrate 110, the orthographic projection of the connection line on the substrate 110 is located outside the orthographic projection of the first via hole 131 on the substrate 110. Similarly, if there is a process error during the fabrication of the connection line and the first via hole 131, it can reduce the difference between different parasitic capacitances when the connection lines in different gate driving circuits overlap with the first light-shielding layer 130 to form different parasitic capacitances, thereby reducing the load difference of the connection lines in different stages of gate driving circuits.

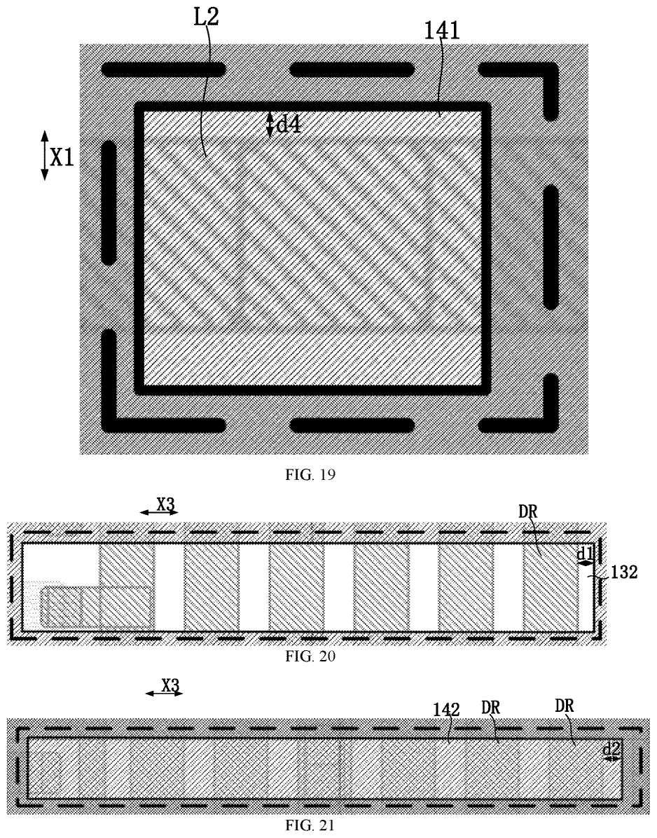

In some embodiments, FIG. 18 is a partially enlarged schematic diagram of a first dashed box P1 in FIG. 5. As shown in FIG. 15, along a second direction X1, an edge of an orthographic projection of a connection line on the substrate 110 and an edge of an orthographic projection of the first via hole 131 on the substrate 110 has a third preset distance d3 therebetween; and the second direction X1 intersects with the extending direction of the connection line.

The second direction X1 may be perpendicular to the extending direction of the connection line. FIG. 18 in an embodiment shows that an angle between the extending direction of the first connection line L1 and a first direction Y is 90°, at which time the second direction X1 is parallel to the first direction Y. When the orthographic projection of the first connection line L1 on the substrate 110 passes through the orthographic projection of the first via hole 131 on the substrate 110, the third preset distance d3 from the edge of the orthographic projection of the first connection line L1 on the substrate 110 to the edge of the orthographic projection of the first via hole 131 on the substrate 110 is located within the first via hole 131.

By setting the third preset distance d3 from the edge of the orthographic projection of the first connection line L1 on the substrate 110 to the edge of the orthographic projection of the first via hole 131 on the substrate 110, if there is a process error during the fabrication of the first connection line L1 and the first via hole 131, the orthographic projection of the first connection line L1 on the substrate 110 can still pass through the orthographic projection of the first via hole 131 on the substrate 110, thereby reducing the difference between different parasitic capacitances when the first connection line L1 in different gate driving circuits overlaps with the first light-shielding layer 130 to form different parasitic capacitances, and thus reducing the load difference of the connection lines in different stages of gate driving circuits.

In an embodiment, when the process error distance is 1.5 μm, the third preset distance d3 may be greater than or equal to 1.5 μm, and the third preset distance d3 is greater than or equal to the range of the process error, ensuring that the orthographic projection of the first connection line L1 on the substrate 110 can still pass through the orthographic projection of the first via hole 131 on the substrate 110.

In other embodiments, the orthographic projection of a connection line on the substrate 110 may also be located outside the orthographic projection of the first via hole 131 on the substrate 110, at which time the third preset distance d3 is located outside the first via hole 131. By setting the third preset distance d3 from the edge of the orthographic projection of the connection line on the substrate 110 to the edge of the orthographic projection of the first via hole 131 on the substrate 110, if there is a process error during the fabrication of the connection line and the first via hole 131, the orthographic projection of the connection line on the substrate 110 can still be located outside the orthographic projection of the first via hole 131 on the substrate 110, thereby reducing the difference between different parasitic capacitances when the connection lines in different gate driving circuits overlap with the first light-shielding layer 130 to form different parasitic capacitances, and thus reducing the load difference of the connection lines in different stages of gate driving circuits.

In some embodiments, as shown in FIG. 2, FIG. 5, FIG. 6, and FIG. 9 to FIG. 18, an orthographic projection of a connection line on the substrate 110 along an extending direction of the connection line passes through an orthographic projection of a second via hole 141 on the substrate 110, or, the orthographic projection of the connection line on the substrate 110 does not overlap with the orthographic projection of the second via hole 141 on the substrate 110.

When the orthographic projection of the connection line on the substrate 110 along the extension direction of the connection line passes through the orthographic projection of the second via hole 141 on the substrate 110, and there is a process error during the fabrication of the connection line and the second via hole 141, it can ensure that the overlapping area between the orthographic projection of the connection line in different gate driving circuits on the substrate 110 and the orthographic projection of the second light-shielding layer 140 on the substrate 110 is equal. Consequently, when different parasitic capacitances are formed by the overlap between the connection lines in different gate driving circuits and the second light-shielding layer 140, the difference between these different parasitic capacitances can be reduced, thereby minimizing the load variation of the connection lines in different stages of gate driving circuits.

In an embodiment, referring to FIG. 6 and FIGS. 14 to 17, the first electrode plate of the third capacitor C3 is connected to the bottom gate of the eighth transistor T8 through the second connection line L2. Along the extension direction of the second connection line L2, the orthographic projection of the second connection line L2 on the substrate 110 passes through the orthographic projection of the second via hole 141 on the substrate 110. When there is a process error during the fabrication of the second connection line L2 and the second via hole 141, it can ensure that the overlapping area between the second connection line L2 in different gate driving circuits and the second light-shielding layer 140 is equal, thereby reducing the difference between different parasitic capacitances and minimizing the load variation of the connection lines in different stages of gate driving circuits.

When the orthographic projection of the connection line on the substrate 110 does not overlap with the orthographic projection of the second via hole 141 on the substrate 110, the orthographic projection of the connection line on the substrate 110 is located outside the orthographic projection of the second via hole 141 on the substrate 110. Similarly, when there is a process error during the fabrication of the connection line and the second via hole 141, it can ensure that when different parasitic capacitances are formed by the overlap between the connection lines in different gate driving circuits and the second light-shielding layer 140, the difference between these different parasitic capacitances can be reduced, thereby minimizing the load variation of the connection lines in different stages of gate driving circuits.

In some embodiments, FIG. 19 is a partial enlarged schematic view of the first dashed box A1 in FIG. 6. As shown in FIG. 19, along the second direction X1, the edge of the orthographic projection of the connection line on the substrate 110 to the edge of the orthographic projection of the second via hole 141 on the substrate 110 has a fourth preset distance d4 therebetween.

FIG. 19 in an embodiment shows that the angle between the extension direction of the second connection line L2 and the first direction Y is 90°, at which point the second direction X1 is parallel to the first direction Y. When the orthographic projection of the second connection line L2 on the substrate 110 passes through the orthographic projection of the second via hole 141 on the substrate 110, the fourth preset distance d4 from the edge of the orthographic projection of the second connection line L2 on the substrate 110 to the edge of the orthographic projection of the second via hole 141 on the substrate 110 is located within the second via hole 141.

By setting the fourth preset distance d4 between the edge of the orthographic projection of the second connection line L2 on the substrate 110 and the edge of the orthographic projection of the second via hole 141 on the substrate 110, when there is a process error during the fabrication of the second connection line L2 and the second via hole 141, the orthographic projection of the second connection line L2 on the substrate 110 can still pass through the orthographic projection of the second via hole 141 on the substrate 110. This ensures that when different parasitic capacitances are formed by the overlap between the second connection line L2 in different gate driving circuits and the second light-shielding layer 140, the difference between these different parasitic capacitances can be reduced, thereby minimizing the load variation of the connection lines in different stages of gate driving circuits.

In an embodiment, when the process error distance is 1.5 μm, the fourth preset distance d4 can be greater than or equal to 1.5 μm, ensuring that the fourth preset distance d4 is greater than or equal to the range of the process error, thereby guaranteeing that the orthographic projection of the second connection line L2 on the substrate 110 can still pass through the orthographic projection of the second via hole 141 on the substrate 110.

In other embodiments, the orthographic projection of the connection line on the substrate 110 may also be located outside the orthographic projection of the second via hole 141 on the substrate 110, in which case the fourth preset distance d4 is located outside the second via hole 141. By setting the fourth preset distance d4 between the edge of the orthographic projection of the connection line on the substrate 110 and the edge of the orthographic projection of the second via hole 141 on the substrate 110, when there is a process error during the fabrication of the connection line and the second via hole 141, the orthographic projection of the connection line on the substrate 110 can still be located outside the orthographic projection of the second via hole 141 on the substrate 110. This ensures that when different parasitic capacitances are formed by the overlap between the connection lines in different gate driving circuits and the second light-shielding layer 140, the difference between these different parasitic capacitances can be reduced, thereby minimizing the load variation of the connection lines in different stages of gate driving circuits.

Continuing to refer to FIGS. 3 to 8, within the same sub-region 101, the first via holes 131 are arranged in rows at intervals along the third direction X2, and adjacent rows of first via holes 131 are staggered; and/or, within the same sub-region 101, the second via holes 141 are arranged in rows at intervals along the third direction X2, and adjacent rows of second via holes 141 are staggered; and the third direction X2 intersects with the first direction Y.

The third direction X2 may be the row direction of the display panel. Within the same sub-region 101, the first via holes 131 are arranged in rows at intervals along the third direction X2, which can make the distribution of the first via holes 131 on the first light-shielding layer 130 relatively uniform, thereby allowing gas on the first insulating layer 150 to uniformly escape through the first via holes 131, improving the uniformity of gas escape from the first insulating layer 150 and avoiding local protrusions or displacement of the first light-shielding layer 130.

Moreover, the first via holes 131 in the same row are arranged at intervals, and the first via holes 131 in two adjacent rows are staggered, meaning that along the first direction Y, the first via holes 131 in the upper row and the first via holes 131 in the lower row are not in the same column. This ensures that the orthographic projection of the second via holes 141 on the substrate 110 can be arranged at intervals with the orthographic projection of the first via holes 131 on the substrate 110, which not only improves the uniformity of gas escape from the first insulating layer 150 and the second insulating layer 160 but also ensures that the orthographic projection of the first via holes 131 on the substrate 110 and the orthographic projection of the second via holes 141 on the substrate 110 do not overlap, thereby maintaining the light-shielding effect.

Similarly, within the same sub-region 101, the second via holes 141 are arranged in rows at intervals along the third direction X2, which can make the distribution of the second via holes 141 on the second light-shielding layer 140 relatively uniform, thereby allowing gas on the second insulating layer 160 to uniformly escape through the second via holes 141, improving the uniformity of gas escape from the second insulating layer 160 and avoiding local protrusions or displacement of the second light-shielding layer 140.

Moreover, the second via holes 141 in the same row are arranged at intervals, and the second via holes 141 in two adjacent rows are staggered, meaning that along the first direction Y, the second via holes 141 in the upper row and the second via holes 141 in the lower row are not in the same column. This ensures that the orthographic projection of the second via holes 141 on the substrate 110 can be arranged at intervals with the orthographic projection of the first via holes 131 on the substrate 110, which not only improves the uniformity of gas escape from the first insulating layer 150 and the second insulating layer 160 but also ensures that the orthographic projection of the first via holes 131 on the substrate 110 and the orthographic projection of the second via holes 141 on the substrate 110 do not overlap, thereby maintaining the light-shielding effect. Continuing to refer to FIGS. 3 to 8, along the third direction X2, within the same sub-region 101, the orthographic projection of the first via holes 131 on the substrate 110 and the orthographic projection of the second via holes 141 on the substrate 110 are arranged in the same row.

As shown in FIGS. 5 to 8, along the third direction X, the orthographic projection of a row of first via holes 131 on the substrate 110 and the orthographic projection of a row of second via holes 141 on the substrate 110 are arranged in the same row. At the same time, the first via holes 131 in two adjacent rows are staggered, and the second via holes 141 in two adjacent rows are staggered. That is, in the same row, the orthographic projection of the first via holes 131 on the substrate 110 and the orthographic projection of the second via holes 141 on the substrate 110 are alternately arranged. This can ensure that the first via holes 131 are uniformly distributed on the first light-shielding layer 130, and the second via holes 141 are uniformly distributed on the second light-shielding layer 140, which not only improves the uniformity of gas escape from the first insulating layer 150 and the second insulating layer 160 but also ensures that the orthographic projection of the first via holes 131 on the substrate 110 and the orthographic projection of the second via holes 141 on the substrate 110 do not overlap, thereby maintaining the light-shielding effect.

Continuing to refer to FIGS. 3 to 8, the number of first via holes 131 in different rows is equal, which can ensure that the number of first via holes 131 in different areas of the first light-shielding layer 130 is equal, thereby improving the distribution uniformity of the first via holes 131 on the first light-shielding layer 130. Continuing to refer to FIGS. 3 to 8, the number of second via holes 141 in different rows is equal, which can ensure that the number of second via holes 141 in different areas of the second light-shielding layer 140 is equal, thereby improving the distribution uniformity of the first via holes 141 on the second light-shielding layer 140. Continuing to refer to FIGS. 3 to 8, the number of rows of first via holes 131 in the same sub-region 101 is equal to the number of rows of second via holes 141, which can ensure that the number of first via holes 131 and the number of second via holes 141 in the same sub-region 101 are equal, and their distribution patterns are the same. This ensures that both the first insulating layer 150 and the second insulating layer 160 have excellent gas escape uniformity, thereby guaranteeing the reliability of the display panel.

In some embodiments, continuing to refer to FIGS. 3 to 8, along the third direction X2, the spacing between adjacent first via holes 131 is less than a fifth preset distance d5; and/or the spacing between adjacent second via holes 141 is less than a sixth preset distance d6; and the third direction X2 intersects with the first direction Y. Along the third direction X2, the spacing between adjacent first via holes 131 being less than the fifth preset distance d5 can ensure the density of the first via holes 131 on the first light-shielding layer 130, thereby ensuring the gas escape efficiency of the first insulating layer 150 and avoiding displacement of the first light-shielding layer 130. In an embodiment, the fifth preset distance d5 is less than or equal to 100 micrometers.

Additionally, the area of the first via holes 131 may be greater than a first preset value, which can also ensure the area of the first light-shielding layer 130 used for gas escape, thereby guaranteeing the gas escape efficiency of the first insulating layer 150 and avoiding displacement of the first light-shielding layer 130. In an embodiment, the first preset value may be greater than or equal to 140 square micrometers. Along the third direction X2, the spacing between adjacent second via holes 141 being less than the sixth preset distance d6 can ensure the density of the second via holes 141 on the second light-shielding layer 140, thereby ensuring the gas escape efficiency of the second insulating layer 160 and avoiding displacement of the second light-shielding layer 140.

In an embodiment, the sixth preset distance d6 is less than or equal to 100 micrometers. Additionally, the area of the second via holes 141 being greater than a second preset value can also ensure the area of the second light-shielding layer 140 used for gas escape, thereby guaranteeing the gas escape efficiency of the second insulating layer 160 and avoiding displacement of the second light-shielding layer 140. In an embodiment, the second preset value may be greater than or equal to 140 square micrometers.

Continuing to refer to FIG. 3 to FIG. 8 and FIG. 14 to FIG. 17, the sub-region 101 further includes a plurality of driving signal lines DR. The driving signal lines DR are disposed on one side of the gate driving circuit GIP and are respectively connected to the multi-stage gate driving circuits GIP. A third via hole 132 is further provided on the first light-shielding layer 130, and a fourth via hole 142 is further provided on the second light-shielding layer 140. The overlapping area of the orthographic projection of the same driving signal line DR on the substrate 110 and the orthographic projection of the third via hole 132 of different sub-regions 101 on the substrate 110 is the same; and/or, the overlapping area of the orthographic projection of the same driving signal line DR on the substrate 110 and the orthographic projection of the fourth via hole 142 of different sub-regions 101 on the substrate 110 is the same. The driving signal line DR is connected to the multi-stage gate driving circuits GIP and is used to provide driving signals to the multi-stage gate driving circuits GIP.

In an embodiment, the driving signal line DR includes at least one of a clock signal line CLK, a start signal line STV, and a first power signal line VGH. The clock signal line CLK provides a clock signal to the gate driving circuit GIP. In an embodiment, in FIG. 9 to FIG. 14, FIG. 17, and FIG. 18, the clock signal line CLK may include at least four lines, namely a first clock signal line CLK1, a second clock signal line CLK2, a third clock signal line CLK3, and a fourth clock signal line CLK4, which respectively provide a first clock signal and a second clock signal to different stages of gate driving circuits GIP.

As shown in FIG. 2, FIG. 5, FIG. 6, and FIG. 14 to FIG. 17, the first clock signal CK1 and the second clock signal CK2 of the gate driving circuit in FIG. 2 are provided through the second clock signal line CLK2 and the fourth clock signal line CLK4, respectively. The start signal line STV can provide a start signal stv to the first-stage gate driving circuit GIP. The first power signal line VGH can provide a first power signal vgh to the gate driving circuit GIP, and the first power signal vgh can be a high-level power supply.

The orthographic projection of at least one of the first light-shielding layer 130 and the second light-shielding layer 140 on the substrate 110 can at least partially cover the orthographic projection of the driving signal line DR on the substrate 110, which can further improve the light-shielding effect of the light-shielding layer on the channel region 121 in the gate driving circuit GIP, improve the consistency of gate driving signals output by different stages of gate driving circuits GIP, and ameliorate the horizontal mura phenomenon of the display panel. At this time, the third via hole 132 can be provided on the first light-shielding layer 130 to ensure the gas escape effect of the first insulating layer 150 in the area where the driving signal line DR is located, and to prevent the first light-shielding layer 130 from shifting. The driving signal line DR and the first light-shielding layer 130 are located in different film layers, and an insulating layer is provided between them. When the orthographic projection of the driving signal line DR on the substrate 110 and the orthographic projection of the first light-shielding layer 130 on the substrate 110 overlap, a parasitic capacitance is formed between the driving signal line DR and the first light-shielding layer 130.

By setting the overlapping area of the orthographic projection of the same driving signal line DR on the substrate 110 and the orthographic projection of the third via hole 132 of different sub-regions 101 on the substrate 110 to be the same, when different parasitic capacitances are formed between the same driving signal line DR and the first light-shielding layer 130 of different sub-regions 101, the difference between the different parasitic capacitances can be reduced. Thus, when the driving signal line DR provides driving signals to different stages of gate driving circuits GIP, the difference in delay time of the driving signals corresponding to different stages of gate driving circuits GIP can be reduced, thereby further improving the consistency of gate driving signals output by different stages of gate driving circuits GIP and ameliorating the horizontal mura phenomenon of the display panel. The driving signal line DR and the second light-shielding layer 140 are located in different film layers, and an insulating layer is provided between them.

When the orthographic projection of the driving signal line DR on the substrate 110 and the orthographic projection of the second light-shielding layer 140 on the substrate 110 overlap, a parasitic capacitance is formed between the driving signal line DR and the second light-shielding layer 140. By setting the overlapping area of the orthographic projection of the same driving signal line DR on the substrate 110 and the orthographic projection of the fourth via hole 142 of different sub-regions 101 on the substrate 110 to be the same, when different parasitic capacitances are formed between the same driving signal line DR and the second light-shielding layer 140 of different sub-regions 101, the difference between the different parasitic capacitances can be reduced. Thus, when the driving signal line DR provides driving signals to different stages of gate driving circuits GIP, the difference in delay time of the driving signals corresponding to different stages of gate driving circuits GIP can be reduced, thereby further improving the consistency of gate driving signals output by different stages of gate driving circuits GIP and ameliorating the horizontal mura phenomenon of the display panel.

Continuing to refer to FIG. 5, FIG. 6, and FIG. 14 to FIG. 17, the display panel further includes a second power signal line VGL for providing a second power signal vgl to the gate driving circuit, and the display panel further includes a third power signal line VGLL for providing a third power signal vgll to the gate driving circuit. The voltage of the third power signal vgll is less than the voltage of the second power signal vgl, and the voltage of the second power signal vgl is less than the voltage of the first power signal vgh.

Continuing to refer to FIG. 9 to FIG. 14, FIG. 17, and FIG. 18, the driving signal line DR includes at least one of a clock signal line CLK, a start signal line STV, and a first power signal line VGH extending along the first direction Y and arranged along the third direction X2; and the third direction X2 intersects the first direction Y. The clock signal line CLK, the start signal line STV, and the first power signal line VGH all extend along the first direction Y and are used to provide corresponding driving signals to different stages of gate driving circuits GIP. The clock signal line CLK, the start signal line STV, and the first power signal line VGH are arranged along the third direction X2, which can optimize the layout arrangement of the display panel. In some embodiments, continuing to refer to FIG. 1, the display panel further includes a second conductive layer. The second conductive layer is disposed between the first conductive layer and the active layer, and the driving signal line DR is located in the second conductive layer.

The second conductive layer may be the source-drain layer 200, and the driving signal line DR is located in the source-drain layer 200, which can reduce the load of the driving signal line DR, thereby reducing the delay and impedance voltage drop of the driving signal. In an embodiment, the material of the driving signal line DR may be metal. In some embodiments, referring to FIG. 6, along the first direction Y, the orthographic projection of the third via 132 on the substrate 110 and the orthographic projection of the fourth via 142 on the substrate 110 are alternately arranged. As shown in FIG. 6, along the first direction Y, the orthographic projection of the third via 132 on the substrate 110 and the orthographic projection of the fourth via 142 on the substrate 110 are alternately arranged, which can make the orthographic projection of the third via 132 on the substrate 110 and the orthographic projection of the fourth via 142 on the substrate 110 uniformly distributed, thereby improving the gas escape uniformity of the first insulating layer 150 and the second insulating layer 160 and avoiding displacement of the first light-shielding layer 130 and the second light-shielding layer 140.

In some embodiments, the display panel further includes a control signal line, the display area includes a pixel circuit, and the control signal line is used to connect the pixel circuit and the gate driving circuit; the control signal line is located in the second conductive layer. The gate driving circuit includes a scanning circuit and a light emission control circuit, and the control signal line may include a scanning signal line and a light emission control signal line. The scanning signal line is connected between the output terminal of the scanning circuit and the gate of the switching transistor in the pixel circuit, and the scanning signal is output to the pixel circuit through the scanning signal line. The light emission control signal line is connected between the output terminal of the light emission control circuit and the gate of the light emission control transistor in the pixel circuit, and the light emission control signal is output to the pixel circuit through the light emission control signal line.

The control signal line is located in the second conductive layer, in an embodiment, the source-drain layer of the display panel, which can also reduce the load of the control signal line, thereby reducing the delay and impedance voltage drop of the control signal. Continuing to refer to FIG. 5 and FIG. 6, the orthographic projection of the driving signal line DR on the substrate 110 passes through the orthographic projection of the third via 132 on the substrate 110 along the extending direction of the driving signal line DR; and/or, the orthographic projection of the driving signal line DR on the substrate 110 passes through the orthographic projection of the fourth via 142 on the substrate along the extending direction of the driving signal line DR. When the driving signal line DR extends along the first direction Y, the fourth direction X3 may be parallel to the third direction X2, which is the row direction of the display panel.

When the orthographic projection of the driving signal line DR on the substrate 110 passes through the orthographic projection of the third via 132 on the substrate 110 along the extending direction of the driving signal line DR, if there are process errors during the fabrication of the driving signal line DR and the third via 132, it can make the overlapping area between the orthographic projection of the driving signal line DR connected to different stages of gate driving circuits GIP on the substrate 110 and the orthographic projection of the first light-shielding layer 130 on the substrate 110 equal.

When different parasitic capacitances are formed between the same driving signal line DR and the first light-shielding layers 130 of different sub-regions 101, the difference between different parasitic capacitances can be reduced, thereby reducing the difference in delay time of driving signals corresponding to different stages of gate driving circuits GIP when the driving signal line DR provides driving signals to different stages of gate driving circuits GIP, thus further improving the consistency of gate driving signals output by different stages of gate driving circuits GIP and ameliorating the horizontal mura phenomenon of the display panel.

When the orthographic projection of the driving signal line DR on the substrate 110 passes through the orthographic projection of the fourth via 142 on the substrate along the extending direction of the driving signal line DR, if there are process errors during the fabrication of the driving signal line DR and the fourth via 142, it can make the overlapping area between the orthographic projection of the driving signal line DR connected to different stages of gate driving circuits GIP on the substrate 110 and the orthographic projection of the second light-shielding layer 140 on the substrate 110 equal.

When different parasitic capacitances are formed between the same driving signal line DR and the second light-shielding layers 140 of different sub-regions 101, the difference between different parasitic capacitances can be reduced, thereby reducing the difference in delay time of driving signals corresponding to different stages of gate driving circuits GIP when the driving signal line DR provides driving signals to different stages of gate driving circuits GIP, thus further improving the consistency of gate driving signals output by different stages of gate driving circuits GIP and ameliorating the horizontal mura phenomenon of the display panel. FIG. 20 is a partially enlarged schematic diagram of the second dashed box P2 in FIG. 5. As shown in FIG. 20, along the fourth direction X3, the edge of the orthographic projection of the driving signal line DR on the substrate 110 has a first preset distance d1 from the edge of the orthographic projection of the third via 132 on the substrate 110; and the fourth direction X3 intersects with the extending direction of the driving signal line DR.

The fourth direction X3 may be perpendicular to the extension direction of the driving signal line DR. In an embodiment, if the extension direction of the driving signal line DR is the first direction Y, the fourth direction X3 may be the row direction of the display panel. When the orthographic projection of the driving signal line DR on the substrate 110 passes through the orthographic projection of the third via 132 on the substrate 110, the first preset distance d1 is located within the third via 132. By configuring the edge of the orthographic projection of the driving signal line DR on the substrate 110 to have a first preset distance d1 from the edge of the orthographic projection of the third via 132 on the substrate 110, even if there are process errors during the fabrication of the driving signal line DR and the third via 132, the orthographic projection of the driving signal line DR on the substrate 110 can still pass through the orthographic projection of the third via 132 on the substrate 110. This ensures that the overlapping areas between the orthographic projections of the driving signal lines DR connected to different stages of gate driving circuits GIP on the substrate 110 and the orthographic projection of the first light-shielding layer 130 on the substrate 110 are equal. When the same driving signal line DR forms different parasitic capacitances with the first light-shielding layers 130 in different sub-regions 101, the differences between these parasitic capacitances can be reduced. Consequently, when the driving signal line DR provides driving signals to different stages of gate driving circuits GIP, the differences in delay times of the driving signals corresponding to different stages of gate driving circuits GIP can be minimized. This further improves the consistency of the gate driving signals output by different stages of gate driving circuits GIP and mitigates the horizontal mura phenomenon in the display panel.

In an embodiment, when the process error distance is 1.5 μm, the first preset distance d1 may be greater than or equal to 1.5 μm. Within the process tolerance, this ensures that the orthographic projection of the driving signal line DR on the substrate 110 passes through the orthographic projection of the third via 132 on the substrate 110. When there is no overlap between the orthographic projection of the driving signal line DR on the substrate 110 and the orthographic projection of the third via 132 on the substrate 110, the first preset distance d1 is located outside the third via 132. By configuring the edge of the orthographic projection of the driving signal line DR on the substrate 110 to have a first preset distance d1 from the edge of the orthographic projection of the third via 132 on the substrate 110, even if there are process errors during the fabrication of the driving signal line DR and the third via 132, the orthographic projection of the driving signal line DR on the substrate 110 can still remain outside the orthographic projection of the third via 132 on the substrate 110.

FIG. 21 is a partial enlarged schematic view of the second dashed box A2 in FIG. 6. As shown in FIG. 21, along the fourth direction X3, the edge of the orthographic projection of the driving signal line DR on the substrate 110 has a second preset distance d2 from the edge of the orthographic projection of the fourth via 142 on the substrate 110. When the orthographic projection of the driving signal line DR on the substrate 110 passes through the orthographic projection of the fourth via 142 on the substrate 110, the second preset distance d2 is located within the fourth via 142.

By configuring the edge of the orthographic projection of the driving signal line DR on the substrate 110 to have a second preset distance d2 from the edge of the orthographic projection of the fourth via 142 on the substrate 110, even if there are process errors during the fabrication of the driving signal line DR and the fourth via 142, the orthographic projection of the driving signal line DR on the substrate 110 can still pass through the orthographic projection of the fourth via 142 on the substrate 110.

This ensures that the overlapping areas between the orthographic projections of the driving signal lines DR connected to different stages of gate driving circuits GIP on the substrate 110 and the orthographic projection of the second light-shielding layer 140 on the substrate 110 are equal. When the same driving signal line DR forms different parasitic capacitances with the second light-shielding layers 140 in different sub-regions 101, the differences between these parasitic capacitances can be reduced.

Consequently, when the driving signal line DR provides driving signals to different stages of gate driving circuits GIP, the differences in delay times of the driving signals corresponding to different stages of gate driving circuits GIP can be minimized. This further improves the consistency of the gate driving signals output by different stages of gate driving circuits GIP and mitigates the horizontal mura phenomenon in the display panel.

In an embodiment, when the process error distance is 1.5 μm, the second preset distance d2 may be greater than or equal to 1.5 μm. Within the process tolerance, this ensures that the orthographic projection of the driving signal line DR on the substrate 110 passes through the orthographic projection of the fourth via 142 on the substrate 110. When there is no overlap between the orthographic projection of the driving signal line DR on the substrate 110 and the orthographic projection of the fourth via 142 on the substrate 110, the second preset distance d2 is located outside the fourth via 142.

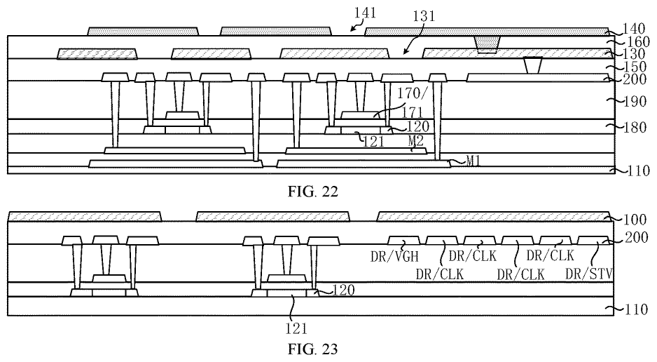

By configuring the edge of the orthographic projection of the driving signal line DR on the substrate 110 to have a first preset distance d1 from the edge of the orthographic projection of the fourth via 142 on the substrate 110, even if there are process errors during the fabrication of the driving signal line DR and the fourth via 142, the orthographic projection of the driving signal line DR on the substrate 110 can still remain outside the orthographic projection of the fourth via 142 on the substrate 110. FIG. 22 is a schematic cross-sectional structural diagram of another display panel provided by an embodiment of the present application.

As shown in FIG. 22, the display panel further includes a gate 171, and the orthographic projection of the gate 171 on the substrate 110 overlaps with the orthographic projection of the channel region 121 on the substrate 110. The gate 171 may be a conductive structure, and the orthographic projection of the gate 171 on the substrate 110 overlaps with the orthographic projection of the channel region 121 on the substrate 110 to form a transistor.

In an embodiment, as shown in FIG. 22, the display panel further includes a third conductive layer disposed between the active layer 120 and the second conductive layer, and the gate 171 is located in the third conductive layer. The third conductive layer may be a gate layer 170, and the gates 171 of individual transistors are formed by patterning the gate layer 170. Continuing with reference to FIG. 22, the display panel further includes: a fourth conductive layer disposed between the substrate and the active layer, and the orthographic projection of the fourth conductive layer on the substrate at least overlaps with the orthographic projection of the channel region on the substrate.

As shown in FIG. 22, the fourth conductive layer may be a second metal layer M2 disposed between the substrate 110 and the active layer 120. When the orthographic projection of the fourth conductive layer on the substrate 110 at least overlaps with the orthographic projection of the channel region 121 on the substrate 110, the fourth conductive layer may serve as a bottom gate of the transistor, realizing a dual-gate structure of the transistor.

In some embodiments, the fourth conductive layer may also serve as a light-shielding layer for blocking light from the substrate 110 side from irradiating the channel region 121, further improving the threshold voltage stability of the transistor and enhancing the display effect of the display panel.

In an embodiment, the orthographic projection of the channel region 121 on the substrate 110 is located within the orthographic projection of the fourth conductive layer on the substrate 110, which can ensure the light-shielding effect on the channel region 121.

Continuing to refer to FIG. 22, the display panel further includes a fifth conductive layer disposed between the substrate and the fourth conductive layer, and the orthographic projection of the fifth conductive layer on the substrate overlaps with the orthographic projection of the fourth conductive layer on the substrate.

As shown in FIG. 22, the fifth conductive layer may be a first metal layer M1 disposed between the fourth conductive layer and the substrate 110. When the orthographic projection of the fifth conductive layer on the substrate overlaps with the orthographic projection of the fourth conductive layer on the substrate, the fifth conductive layer may serve as a light-shielding layer for blocking light from the substrate 110 side from irradiating the channel region 121, further improving the threshold voltage stability of the transistor and enhancing the display effect of the display panel.

In some embodiments, the display panel further includes a fixed voltage signal line; the first light-shielding layer is connected to the fixed voltage signal line.

The fixed voltage signal line is used to provide a fixed voltage to the display panel. In an embodiment, the fixed voltage signal line may be an initialization signal line or a power signal line. Connecting the first light-shielding layer to the fixed voltage signal line allows the first light-shielding layer to have a fixed potential. When a parasitic capacitance exists between the first light-shielding layer and the transistor, this parasitic capacitance can be prevented from affecting the potential and its variation of the transistor, thereby improving the display effect of the display panel.

In some embodiments, the fixed voltage signal line includes a first power signal line or a second power signal line. The first power signal line is connected to the gate driving circuit and is used to provide a first power signal to the gate driving circuit; the second power signal line is connected to the gate driving circuit and is used to provide a second power signal to the gate driving circuit.

In some embodiments, the first power signal may be a high-level signal, and the second power signal may be a low-level signal, used to supply power to the gate driving circuit. In an embodiment, referring to FIG. 2, the gate driving circuit includes 10 transistors. The first power signal line VGH may supply power to the first electrode of the third transistor T3 and the gate of the sixth transistor T6. The second power signal line VGL may supply power to the first electrode of the fourth transistor T4 and the first electrode of the seventh transistor T7. Both the first power signal line VGH and the second power signal line VGL are fixed potential signals. The first light-shielding layer may be connected to the first power signal line or the second power signal line, allowing the first light-shielding layer to have a fixed potential.

In some embodiments, the fixed voltage signal line is located in at least one of the first conductive layer, the second conductive layer, and the electrode layer.

In some embodiments, the second conductive layer may be a source-drain layer, such as a third metal layer. The first conductive layer is disposed on a side of the second conductive layer away from the substrate, such as a fourth metal layer. The electrode layer is disposed on a side of the first conductive layer away from the substrate and may form electrodes of light-emitting devices in the display area. The fixed potential signal line may be located in the non-display area and in at least one of the first conductive layer, the second conductive layer, and the electrode layer, which can simplify the layout design of the display panel and reduce the load impedance of the fixed potential signal line. In an embodiment, when the fixed potential signal line is the second power signal line, it may be simultaneously located in the first conductive layer, the second conductive layer, and the electrode layer to reduce the load impedance of the fixed potential signal line.

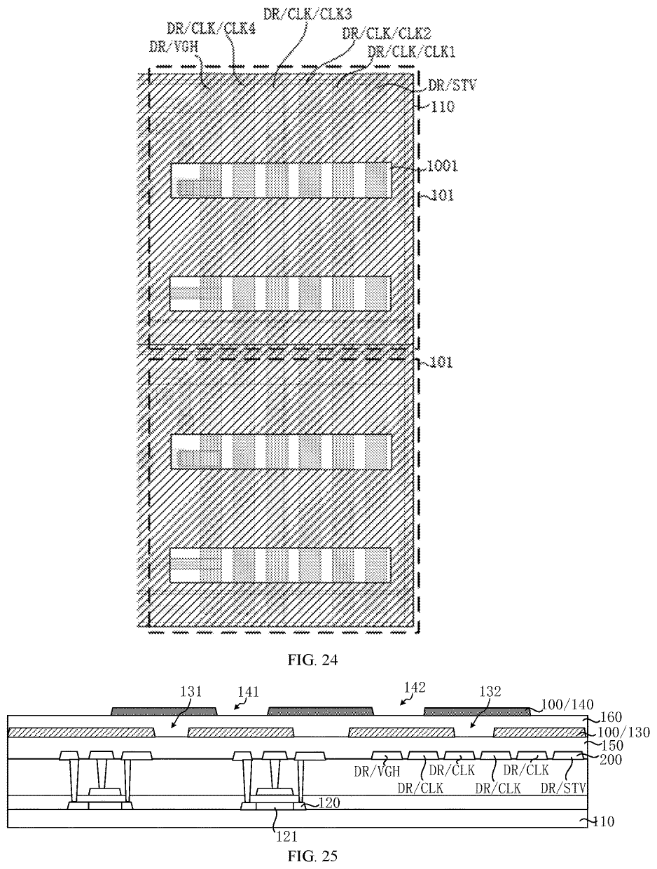

The embodiments of the present application also provide a display panel. FIG. 23 is a schematic cross-sectional structural diagram of another display panel provided by an embodiment of the present application, and FIG. 24 is a schematic top-view structural diagram of a driving signal line and a light-shielding layer provided by an embodiment of the present application. As shown in FIG. 23 and FIG. 24, the display panel includes a plurality of sub-regions 101 and a driving signal line DR. The arrangement direction of the sub-regions 101 is the same as the extending direction of the driving signal line DR. The display panel further includes: a substrate 110; a second conductive layer 200 disposed on one side of the substrate 110, with the driving signal line DR located in the second conductive layer 200; at least one light-shielding layer 100 disposed on a side of the second conductive layer 200 away from the substrate 110, and the overlapping area between the orthographic projection of the same driving signal line DR on the substrate 110 and the orthographic projections of the light-shielding layers 100 of different sub-regions 101 on the substrate 110 is the same.

In some embodiments, the display panel includes a driving circuit, and the driving signal line DR is used to provide a driving signal to the driving circuit. In an embodiment, when the driving circuit is located in the non-display area, the driving circuit may be a gate driving circuit, which may include a scan signal and/or an emission control signal. In this case, the driving signal line DR may include a start signal line STV, a clock signal line CLK, a first power signal line VGH, etc., which are used to provide a start signal, a clock signal, and a first power signal to the cascaded gate driving circuits, respectively. The extending direction of the driving signal line DR may be the cascading direction of the gate driving circuits, such as the column direction of the display panel, and the arrangement direction of the sub-regions 101 is the column direction of the display panel. In this case, the driving signal line DR provides driving signals to the gate driving circuits within each sub-region 101.

The display panel further includes a driving circuit layer for forming transistors in the driving circuit. As shown in FIG. 23 and FIG. 24, the second conductive layer 200 may be a source-drain layer for forming the source and drain of the transistors. The driving circuit layer may further include an active layer 120 for forming the channel region 121 of the transistors. The sub-regions 101 may be divided according to the number of rows of the display panel. In an embodiment, each sub-region 101 may correspond to at least one row of pixels of the display panel and/or correspond to at least one stage of the gate driving circuit of the display panel, and different sub-regions 101 correspond to an equal number of rows.

The light shielding layer 100 is disposed on a side of the second conductive layer 200 away from the substrate 110, and is used to block light incident from the side away from the substrate 110 from irradiating the channel region 121, thereby improving the stability of the material properties of the channel region 121, and thus enhancing the threshold voltage stability of the transistor. The light shielding layer 100 and the second conductive layer 200 are arranged in different layers, with an insulating layer interposed therebetween. When an orthographic projection of the light shielding layer 100 on the substrate 110 overlaps with an orthographic projection of the second conductive layer 200 on the substrate 110, a parasitic capacitance is formed between the light shielding layer 100 and the second conductive layer 200. The driving signal line DR is located in the second conductive layer 200.

When the overlapping area between the orthographic projection of the same driving signal line DR on the substrate 110 and the orthographic projection of the light shielding layer 100 of different sub-regions 101 on the substrate 110 is the same, the difference between different parasitic capacitances can be reduced when different parasitic capacitances are formed between the same driving signal line DR and the light shielding layers 100 of different sub-regions 101.

This improves the load consistency of circuit structures in different sub-regions 101 and the delay consistency of driving signals, thereby mitigating the horizontal mura phenomenon of the display panel. In an embodiment, when each sub-region 101 corresponds to a stage of gate driving circuit in the display panel, the driving signal line DR may include a start signal line STV, a clock signal line CLK, and a first power signal line VGH. When the overlapping area between the orthographic projection of the same driving signal line DR on the substrate 110 and the orthographic projection of the light shielding layer 100 of different sub-regions 101 on the substrate 110 is the same, the difference between different parasitic capacitances can be reduced when different parasitic capacitances are formed between the same driving signal line DR and the light shielding layers 100 of different sub-regions 101.

This improves the load consistency of different stages of gate driving circuits and the delay consistency of gate driving signals, thereby mitigating the horizontal mura phenomenon of the display panel. In this embodiment, by setting the overlapping area between the orthographic projection of the same driving signal line on the substrate and the orthographic projection of the light shielding layers of different sub-regions on the substrate to be the same, the difference between different parasitic capacitances can be reduced when different parasitic capacitances are formed between the same driving signal line and the light shielding layers of different sub-regions. This improves the load consistency of circuit structures in different sub-regions and the delay consistency of driving signals, thereby mitigating the horizontal mura phenomenon of the display panel.

Continuing to refer to FIG. 23 and FIG. 24, at least two through-holes 1001 are provided on the light shielding layer 100. The through-holes 1001 of the same light shielding layer 100 are located in at least two sub-regions 101, and the overlapping area between the orthographic projection of the same driving signal line DR on the substrate 110 and the orthographic projection of the through-holes 1001 of different sub-regions 101 on the substrate 110 is the same. Referring to FIG. 23 and FIG. 24, the display panel includes a single light shielding layer 100, on which four through-holes 1001 are provided, located in two adjacent sub-regions 101, respectively. Each sub-region 101 has two through-holes 1001 arranged along the extension direction of the driving signal line DR.

When gas escapes from a film layer on the side of the light shielding layer 100 close to the substrate 110, the gas can escape through the through-holes 1001, preventing the light shielding layer 100 from shifting under the influence of the gas, thereby ensuring the reliability of the display panel. When the overlapping area between the orthographic projection of the same driving signal line DR on the substrate 110 and the orthographic projection of the through-holes 1001 of different sub-regions 101 on the substrate 110 is the same, the difference between different parasitic capacitances can be reduced when different parasitic capacitances are formed between the same driving signal line DR and the light shielding layers 100 of different sub-regions 101. This improves the load consistency of circuit structures in different sub-regions 101 and the delay consistency of driving signals, thereby mitigating the horizontal mura phenomenon of the display panel.

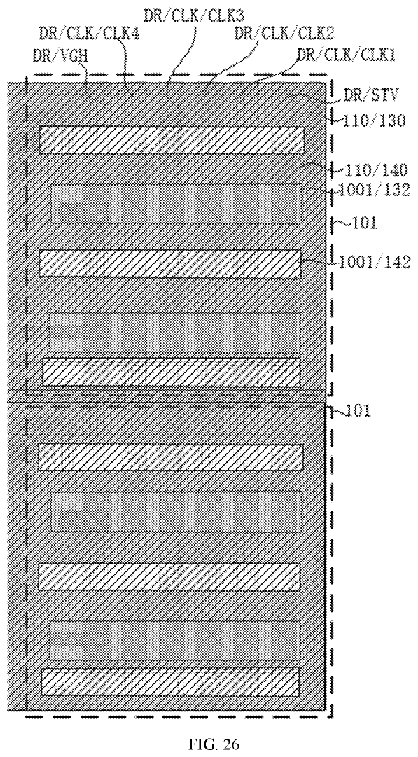

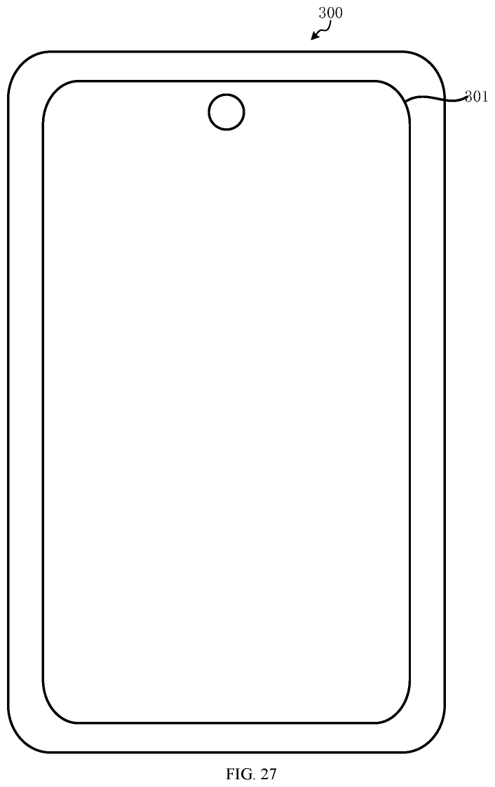

FIG. 25 is a schematic cross-sectional structural diagram of another display panel provided by an embodiment of the present application, and FIG. 26 is a schematic top-view structural diagram of a driving signal line, a first light shielding layer, and a second light shielding layer provided by an embodiment of the present application.

As shown in FIG. 25 to FIG. 26, the light shielding layer 100 includes a first light shielding layer 130 and a second light shielding layer 140. The first light shielding layer 130 and the second light shielding layer 140 are stacked. The first light shielding layer 130 is provided with a third through-hole 132, and the second light shielding layer 140 is provided with a fourth through-hole 142. The overlapping area between the orthographic projection of the same driving signal line DR on the substrate 110 and the orthographic projection of the third through-hole 132 of different sub-regions 101 on the substrate 110 is the same; and/or, the overlapping area between the orthographic projection of the same driving signal line DR on the substrate 110 and the orthographic projection of the fourth through-hole 142 of different sub-regions 101 on the substrate 110 is the same.

In some embodiments, the driving signal line DR may be located in the non-display area and connected to the multi-stage gate driving circuit, for providing driving signals to the multi-stage gate driving circuit. The orthographic projection of each of the first light-shielding layer 130 and the second light-shielding layer 140 on the substrate 110 may partially cover the orthographic projection of the driving signal line DR on the substrate 110, while the orthographic projection of the first light-shielding layer 130 on the substrate 110 and the orthographic projection of the second light-shielding layer 140 on the substrate 110 may completely cover the orthographic projection of the driving signal line DR on the substrate 110, and the first light-shielding layer 130 and the second light-shielding layer 140 can completely shield light around the circuit structure, further improving the light-shielding effect of the light-shielding layer on the channel region of the circuit structure, enhancing the consistency of driving signals output by the circuit structures in different sub-regions 101, and improving the horizontal mura phenomenon of the display panel.

The overlapping area between the orthographic projection of the same driving signal line DR on the substrate 110 and the orthographic projection of the third via hole 132 of different sub-regions 101 on the substrate 110 is the same, which can make the overlapping area between the orthographic projection of the same driving signal line DR on the substrate 110 and the orthographic projection of the first light-shielding layer 130 of different sub-regions 101 on the substrate 110 the same.

When different parasitic capacitances are formed between the same driving signal line DR and the first light-shielding layer 130 of different sub-regions 101, the difference between the different parasitic capacitances can be reduced, thereby improving the load consistency of the circuit structures in different sub-regions 101 and the delay consistency of the driving signals, and improving the horizontal mura phenomenon of the display panel. The overlapping area between the orthographic projection of the same driving signal line DR on the substrate 110 and the orthographic projection of the fourth via hole 142 of different sub-regions 101 on the substrate 110 is the same, which can reduce the difference between different parasitic capacitances when different parasitic capacitances are formed between the same driving signal line DR and the second light-shielding layer 140 of different sub-regions 101, thereby improving the load consistency of the circuit structures in different sub-regions 101 and the delay consistency of the driving signals, and improving the horizontal mura phenomenon of the display panel.

Continuing to refer to FIG. 25 to FIG. 26, along the first direction Y, the orthographic projection of the third via hole 132 on the substrate 110 and the orthographic projection of the fourth via hole 142 on the substrate 110 are alternately arranged.

In some embodiments, the first direction Y may be the extending direction of the driving signal line DR. By arranging the orthographic projection of the third via hole 132 on the substrate 110 and the orthographic projection of the fourth via hole 142 on the substrate 110 alternately, the orthographic projection of the third via hole 132 on the substrate 110 and the orthographic projection of the fourth via hole 142 on the substrate 110 can be uniformly distributed, improving the gas release uniformity of the film layer on the side of the light-shielding layer 100 close to the substrate 110, and avoiding displacement of the first light-shielding layer 130 and the second light-shielding layer 140.

In an embodiment, the display panel further includes a first insulating layer 150 and a second insulating layer 160. The first insulating layer 150 is disposed between the substrate 110 and the first light-shielding layer 130, and the second insulating layer 160 is disposed between the first insulating layer 150 and the second light-shielding layer 140. The materials of the first insulating layer 150 and the second insulating layer 160 may be organic materials, which can improve the gas release uniformity of the first insulating layer 150 and the second insulating layer 160, avoiding displacement of the first light-shielding layer 130 and the second light-shielding layer 140. In an embodiment, the first insulating layer 150 may be a first planarization layer, and the second insulating layer 160 may be a second planarization layer.

Continuing to refer to FIG. 25 to FIG. 26, the driving signal line includes at least one of a clock signal line CLK, a start signal line STV, and a first power signal line VGH extending along the first direction Y and arranged along the third direction X2; and the first direction Y is the arrangement direction of the sub-regions 101, and the third direction X2 intersects the first direction Y.

In some embodiments, the display panel further includes a first conductive layer and an electrode layer. The first conductive layer is disposed on a side of the second conductive layer away from the substrate, and the electrode layer is disposed on a side of the first conductive layer away from the substrate. The first light-shielding layer is formed in the first conductive layer, and the second light-shielding layer is formed in the electrode layer.

In some embodiments, the display panel includes a display area and a non-display area at least partially surrounding the display area; the driving signal line is disposed in the non-display area, and the circuit structure in each sub-region may be a gate driving circuit. By setting the overlapping area between the orthographic projection of the driving signal line on the substrate and the orthographic projection of the light-shielding layer of different sub-regions on the substrate to be the same, the consistency of gate driving signals output by different stages of gate driving circuits can be improved, thereby improving the horizontal mura phenomenon of the display panel.

In some embodiments, the non-display area includes multi-stage cascaded gate driving circuits, and the first direction is the cascading direction of the gate driving circuits.

In some embodiments, the display area includes an electrode of a light-emitting device, and the electrode is located in the electrode layer.

In some embodiments, the electrode is insulated from the second light-shielding layer.

In some embodiments, the display panel further includes a control signal line. The display area includes a pixel circuit, and the control signal line is used to connect the pixel circuit and the gate driving circuit; the control signal line is located in the second conductive layer.

Continuing to refer to FIG. 25 to FIG. 26, the orthographic projection of the driving signal line DR on the substrate 110 passes through the orthographic projection of the third via hole 132 on the substrate 110 along the extending direction of the driving signal line DR; and/or, the orthographic projection of the driving signal line DR on the substrate 110 passes through the orthographic projection of the fourth via hole 142 on the substrate 110 along the extending direction of the driving signal line DR.

In some embodiments, along a fourth direction, the edge of the orthographic projection of the driving signal line on the substrate to the edge of the orthographic projection of the third via hole on the substrate has a first preset distance; and the fourth direction intersects the extending direction of the driving signal line.

The first preset distance is greater than or equal to 1.5 μm.

In some embodiments, along the fourth direction, the edge of the orthographic projection of the driving signal line on the substrate to the edge of the orthographic projection of the fourth via hole on the substrate has a second preset distance.

The second preset distance is greater than or equal to 1.5 μm.

In some embodiments, along the third direction, the gate driving circuit is disposed on one side of the driving signal line, the first light shielding layer is further provided with a first via hole, and the second light shielding layer is further provided with a second via hole; the arrangement of the first via hole and/or the second via hole is the same in different stages of gate driving circuits.

The gate driving circuits of different stages are respectively disposed in different sub-regions; the arrangement of the first via hole is the same in different sub-regions, and/or the arrangement of the second via hole is the same in different sub-regions.

The gate driving circuit includes a transistor, a connection line, and a capacitor, the connection line being used to connect the transistor and the capacitor; the overlapping area between the orthographic projection of the same connection line on the substrate and the orthographic projection of the first via hole in different sub-regions on the substrate is the same; and/or, the overlapping area between the orthographic projection of the same connection line on the substrate and the orthographic projection of the second via hole in different sub-regions on the substrate is the same.

In some embodiments, the orthographic projection of the connection line on the substrate passes through the orthographic projection of the first via hole on the substrate along the extending direction of the connection line, or, the orthographic projection of the connection line on the substrate does not overlap with the orthographic projection of the first via hole on the substrate.

In some embodiments, along the second direction, the edge of the orthographic projection of the connection line on the substrate to the edge of the orthographic projection of the first via hole on the substrate has a third preset distance; and, the second direction intersects with the extending direction of the connection line.

The third preset distance is greater than or equal to 1.5 μm.

The orthographic projection of the connection line on the substrate passes through the orthographic projection of the second via hole on the substrate along the extending direction of the connection line, or, the orthographic projection of the connection line on the substrate does not overlap with the orthographic projection of the second via hole on the substrate.

In some embodiments, along the second direction, the edge of the orthographic projection of the connection line on the substrate to the edge of the orthographic projection of the second via hole on the substrate has a fourth preset distance.

The fourth preset distance is greater than or equal to 1.5 μm.

The embodiments of the present application also provide a display device. FIG. 27 is a schematic structural diagram of a display device provided by an embodiment of the present application. As shown in FIG. 27, the display device includes the display panel provided by any embodiment of the present application. Since the display device 300 includes the display panel 301 provided by any embodiment of the present application, it has the same beneficial effects as the display panel 301 provided by any embodiment of the present application, which will not be repeated here. The display device 300 may be, in an embodiment, any product or component with a display function, such as a mobile phone, tablet computer, television, monitor, laptop, digital photo frame, smart wearable device, information query machine in public hall, etc.

Note that the above are only preferred embodiments of the present application and the technical principles applied. The present application is not limited to the specific embodiments described herein, and various changes, readjustments, and substitutions can be made in the art without departing from the protection scope of the present application. Therefore, although the present application has been described in detail through the above embodiments, the present application is not limited to the above embodiments, and may include more other equivalent embodiments without departing from the concept of the present application, and the scope of

the present application is determined by the appended claims.

1. A display panel, comprising:
a substrate;
an active layer disposed on one side of the substrate, the active layer comprising a plurality of channel regions, the channel regions being used to form a plurality of transistors; and
at least two light-shielding layers stacked on a side of the active layer away from the substrate, wherein an orthographic projection of at least one of the light-shielding layers on the substrate at least partially overlaps an orthographic projection of the channel region on the substrate, and orthographic projections of the at least two light-shielding layers on the substrate cover the orthographic projection of the channel region on the substrate.

2. The display panel according to claim 1, wherein the light-shielding layers comprise a first light-shielding layer and a second light-shielding layer; the first light-shielding layer and the second light-shielding layer are stacked, the second light-shielding layer is disposed on a side of the first light-shielding layer away from the substrate, and the orthographic projection of the channel region on the substrate is located within an orthographic projection of the first light-shielding layer on the substrate, or the orthographic projection of the channel region on the substrate is located within an orthographic projection of the second light-shielding layer on the substrate;
the display panel further comprises a first conductive layer and an electrode layer, the first conductive layer is disposed on a side of the active layer away from the substrate, the electrode layer is disposed on a side of the first conductive layer away from the substrate, the first light-shielding layer is formed in the first conductive layer, and the second light-shielding layer is formed in the electrode layer.

3. The display panel according to claim 2, further comprising a display area and a non-display area at least partially surrounding the display area; the transistor is disposed in the non-display area and is used to form a gate driving circuit;
the display area comprises an electrode of a light-emitting device, the electrode being located in the electrode layer;
the electrode is insulated from the second light-shielding layer;
the display panel further comprises a first insulating layer and a second insulating layer, the first insulating layer is disposed between the active layer and the first light-shielding layer, and the second insulating layer is disposed between the first light-shielding layer and the second light-shielding layer.

4. The display panel according to claim 3, wherein the non-display area comprises a plurality of sub-areas along a first direction,
the non-display area comprises a plurality of cascaded stages of the gate driving circuit,
the first light-shielding layer is provided with a first via hole, and the second light-shielding layer is provided with a second via hole.

5. The display panel according to claim 4, wherein
an orthographic projection of the first via hole on the substrate does not overlap with an orthographic projection of the second via hole on the substrate;
arrangements of the first via hole or the second via hole are the same in different stages of the gate driving circuit;
different stages of the gate driving circuit are respectively disposed in different sub-areas; arrangements of the first via holes are the same in different sub-areas, or
arrangements of the second via holes are the same in different sub-areas; wherein the first direction is a cascading direction of the gate driving circuit.

6. The display panel according to claim 4, wherein the gate driving circuit further comprises a connection line and a plurality of capacitors, the connection line is used to connect the transistors or the capacitors; an overlapping area between an orthographic projection of the same connection line on the substrate and orthographic projections of the first via holes in different sub-areas on the substrate is the same; or, an overlapping area between an orthographic projection of the same connection line on the substrate and orthographic projections of the second via holes in different sub-areas on the substrate is the same;
an orthographic projection of the connection line on the substrate passes through an orthographic projection of the first via hole on the substrate along an extending direction of the connection line, or the orthographic projection of the connection line on the substrate does not overlap with the orthographic projection of the first via hole on the substrate;
along a second direction, an edge of the orthographic projection of the connection line on the substrate is spaced from an edge of the orthographic projection of the first via hole on the substrate by a third preset distance; wherein the second direction intersects the extending direction of the connection line;
or,
an orthographic projection of the connection line on the substrate passes through an orthographic projection of the second via hole on the substrate along an extending direction of the connection line, or the orthographic projection of the connection line on the substrate does not overlap with the orthographic projection of the second via hole on the substrate;
along a second direction, an edge of the orthographic projection of the connection line on the substrate is spaced from an edge of the orthographic projection of the second via hole on the substrate by a fourth preset distance; wherein the second direction intersects the extending direction of the connection line.

7. The display panel according to claim 4, wherein the first via holes in the same sub-area are arranged in rows spaced apart along a third direction, and adjacent two rows of the first via holes are offset; or, the second via holes in the same sub-area are arranged in rows spaced apart along a third direction, and adjacent two rows of the second via holes are offset; wherein the third direction intersects the first direction;
along the third direction, within the same sub-area, orthographic projections of the first via holes on the substrate and orthographic projections of the second via holes on the substrate are arranged in the same row; or,
along the third direction, within the same sub-area, orthographic projections of the first via holes on the substrate and orthographic projections of the second via holes on the substrate are alternately arranged.

8. The display panel according to claim 4, wherein the sub-region further comprises a plurality of driving signal lines, the driving signal lines are disposed on a side of the gate driving circuit and are respectively connected to multiple stages of the gate driving circuit; a third via hole is further disposed on the first light-shielding layer, and a fourth via hole is further disposed on the second light-shielding layer;
overlapping areas between an orthographic projection of a same driving signal line on the substrate and orthographic projections of the third via holes of different sub-regions on the substrate are the same; or,
overlapping areas between an orthographic projection of a same driving signal line on the substrate and orthographic projections of the fourth via holes of different sub-regions on the substrate are the same.

9. The display panel according to claim 8, further comprising a second conductive layer, the second conductive layer is disposed between the first conductive layer and the active layer, and the driving signal lines are located in the second conductive layer;
along the first direction, orthographic projections of the third via hole on the substrate and orthographic projections of the fourth via hole on the substrate are alternately arranged;
the display panel further comprises a control signal line, the display area comprises a pixel circuit, the control signal line is configured to connect the pixel circuit and the gate driving circuit; and the control signal line is located in the second conductive layer.

10. The display panel according to claim 8, wherein an orthographic projection of the driving signal line on the substrate passes through an orthographic projection of the third via hole on the substrate along an extending direction of the driving signal line; or,
an orthographic projection of the driving signal line on the substrate passes through an orthographic projection of the fourth via hole on the substrate along an extending direction of the driving signal line;
along a fourth direction, an edge of an orthographic projection of the driving signal line on the substrate and an edge of an orthographic projection of the third via hole on the substrate has a first preset distance therebetween; wherein the fourth direction intersects the extending direction of the driving signal line; or,
along the fourth direction, an edge of an orthographic projection of the driving signal line on the substrate and an edge of an orthographic projection of the fourth via hole on the substrate has a second preset distance therebetween; wherein the fourth direction intersects the extending direction of the driving signal line.

11. The display panel according to claim 7, wherein the driving signal line comprises at least one of a clock signal line, a start signal line, and a first power signal line extending along the first direction and arranged along a third direction; wherein the third direction intersects the first direction,
the display panel comprises a gate, wherein an orthographic projection of the gate on the substrate overlaps an orthographic projection of the channel region on the substrate;
the display panel further comprises a third conductive layer disposed between the active layer and the second conductive layer, and the gate is located in the third conductive layer.

12. The display panel according to claim 4, wherein along a third direction, a spacing between adjacent first via holes is less than a fifth preset distance, and the fifth preset distance is less than or equal to 100 micrometers; or,
a spacing between adjacent second via holes is less than a sixth preset distance, and the sixth preset distance is less than or equal to 100 micrometers; wherein the third direction intersects the first direction.

13. The display panel according to claim 4, further comprising a fixed voltage signal line; the first light-shielding layer is connected to the fixed voltage signal line;
the fixed voltage signal line comprises a first power signal line or a second power signal line, the first power signal line is connected to the gate driving circuit and is configured to provide a first power signal to the gate driving circuit; the second power signal line is connected to the gate driving circuit and is configured to provide a second power signal to the gate driving circuit; and
the fixed voltage signal line is located in at least one of the first conductive layer, the second conductive layer, and an electrode layer.

14. The display panel according to claim 1, further comprising: a fourth conductive layer disposed between the substrate and the active layer, wherein an orthographic projection of the fourth conductive layer on the substrate at least overlaps an orthographic projection of the channel region on the substrate; the fourth conductive layer serves as a light-shielding layer.

15. The display panel according to claim 14, further comprising: a fifth conductive layer disposed between the substrate and the fourth conductive layer, wherein an orthographic projection of the fifth conductive layer on the substrate overlaps an orthographic projection of the fourth conductive layer on the substrate; the fifth conductive layer serves as a light-shielding layer.

16. A display panel, comprising a plurality of sub-regions and a plurality of driving signal lines, wherein an arrangement direction of the sub-regions is the same as an extending direction of the driving signal lines; the display panel further comprises:
a substrate;
a second conductive layer disposed on a side of the substrate, wherein the driving signal lines are located in the second conductive layer;
at least one light-shielding layer disposed on a side of the second conductive layer away from the substrate, wherein overlapping areas between an orthographic projection of a same driving signal line on the substrate and orthographic projections of the light-shielding layers of different sub-regions on the substrate are the same.

17. The display panel according to claim 16, wherein at least two through holes are provided on the light shielding layer, the through holes of the same light shielding layer are located in at least two of the sub-regions, and overlapping areas between an orthographic projection of the same driving signal line on the substrate and orthographic projections of the through holes in different sub-regions on the substrate are the same;
the light shielding layer comprises a first light shielding layer and a second light shielding layer; the first light shielding layer and the second light shielding layer are stacked, a third through hole is provided on the first light shielding layer, and a fourth through hole is provided on the second light shielding layer;
overlapping areas between an orthographic projection of the same driving signal line on the substrate and orthographic projections of the third through holes in different sub-regions on the substrate are the same; or,
overlapping areas between an orthographic projection of the same driving signal line on the substrate and orthographic projections of the fourth through holes in different sub-regions on the substrate are the same;
along a first direction, orthographic projections of the third through holes on the substrate and orthographic projections of the fourth through holes on the substrate are alternately arranged;
the display panel further comprises a control signal line, the display area comprises a pixel circuit, and the control signal line is configured to connect the pixel circuit and a gate driving circuit; the control signal line is located in the second conductive layer;
the display panel further comprises a first conductive layer and an electrode layer, the first conductive layer is disposed on a side of the second conductive layer away from the substrate, the electrode layer is disposed on a side of the first conductive layer away from the substrate, the first light shielding layer is located on the first conductive layer, and the second light shielding layer is located on the electrode layer;
the display panel comprises a display area and a non-display area at least partially surrounding the display area; the driving signal line is disposed in the non-display area;
the driving signal line comprises at least one of a clock signal line, a start signal line, and a first power signal line extending along the first direction and arranged along a third direction; wherein the first direction is an arrangement direction of the sub-regions, and the third direction intersects the first direction;
the display area comprises an electrode of a light-emitting device, and the electrode is formed in the electrode layer;
the electrode is insulated from the second light shielding layer;
the non-display area comprises multi-stage cascaded gate driving circuits, and the first direction is a cascading direction of the gate driving circuits;
the display panel further comprises a first insulating layer and a second insulating layer, the first insulating layer is disposed between the substrate and the first light shielding layer, and the second insulating layer is disposed between the first light shielding layer and the second light shielding layer.

18. The display panel according to claim 17, wherein an orthographic projection of the driving signal line on the substrate passes through an orthographic projection of the third through hole on the substrate along an extending direction of the driving signal line; or,
an orthographic projection of the driving signal line on the substrate passes through an orthographic projection of the fourth through hole on the substrate along an extending direction of the driving signal line;
along a fourth direction, an edge of an orthographic projection of the driving signal line on the substrate to an edge of an orthographic projection of the third through hole on the substrate has a first preset distance therebetween; wherein the fourth direction intersects the extending direction of the driving signal line; or,
along the fourth direction, an edge of an orthographic projection of the driving signal line on the substrate to an edge of an orthographic projection of the fourth through hole on the substrate has a second preset distance therebetween; wherein the fourth direction intersects the extending direction of the driving signal line.

19. The display panel according to claim 17, wherein along the third direction, the gate driving circuit is disposed on one side of the driving signal line, a first through hole is further provided on the first light shielding layer, and a second through hole is further provided on the second light shielding layer; an arrangement of the first through holes or the second through holes in different stages of the gate driving circuits is the same; the gate driving circuits of different stages are respectively disposed in different sub-regions; an arrangement of the first through holes in different sub-regions is the same, or an arrangement of the second through holes in different sub-regions is the same;
the gate driving circuit comprises a transistor, a connection line, and a capacitor, and the connection line is configured to connect the transistor and the capacitor;
overlapping areas between an orthographic projection of the same connection line on the substrate and orthographic projections of the first through holes in different sub-regions on the substrate are the same; or,
overlapping areas between an orthographic projection of the same connection line on the substrate and orthographic projections of the second through holes in different sub-regions on the substrate are the same.

20. The display panel according to claim 19, wherein an orthographic projection of the connection line on the substrate passes through an orthographic projection of the first through hole on the substrate along an extending direction of the connection line, or an orthographic projection of the connection line on the substrate does not overlap with an orthographic projection of the first through hole on the substrate;
along a second direction, an edge of an orthographic projection of the connection line on the substrate to an edge of an orthographic projection of the first through hole on the substrate has a third preset distance therebetween; wherein the second direction intersects the extending direction of the connection line;
or,
an orthographic projection of the connection line on the substrate passes through an orthographic projection of the second through hole on the substrate along an extending direction of the connection line, or an orthographic projection of the connection line on the substrate does not overlap with an orthographic projection of the second through hole on the substrate;
along the second direction, an edge of an orthographic projection of the connection line on the substrate to an edge of an orthographic projection of the second through hole on the substrate has a fourth preset distance therebetween; wherein the second direction intersects the extending direction of the connection line.
